(19) United States
(12) Patent Application Publication
(10) Pub. No.: US 2026/0334024 A1
(43) Pub. Date: Oct. 22, 2026

(54) DISPLAY DEVICE AND ELECTRONIC DEVICE INCLUDING THE SAME

(71) Applicant: Samsung Display Co., Ltd., Yongin-si (KR)

(72) Inventors: Junghun LEE, Yongin-si (KR); Chang-Hee WON, Yongin-si (KR); Sung-Ki JUNG, Yongin-si (KR)

(73) Assignee: Samsung Display Co., Ltd., Yongin-si (KR)

(21) Appl. No.: 19/425,284

(22) Filed: Dec. 18, 2025

(30) Foreign Application Priority Data
Apr. 16, 2025 (KR) 10-2025-0049255

(51) Int. Cl. H10K 59/126; G06F 3/044; G06F 3/046; H10K 59/124; H10K 59/40; H10K 102/00

(52) U.S. Cl. CPC H10K 59/126; G06F 3/0446; G06F 3/046; H10K 59/124; H10K 59/40; G06F 2203/04102; G06F 2203/04106; G06F 2203/04107; G06F 2203/04114; H10K 2102/311

(57) ABSTRACT

A display device includes a display panel including a folding area; an input sensing part on the display panel, configured to sense a first input generated by a user’s touch and a second input generated by a pen; a barrier layer under the display panel; an electromagnetic shielding layer under the barrier layer; a first adhesive layer between the barrier layer and the electromagnetic shielding layer; and a first planarization layer between the first adhesive layer and the electromagnetic shielding layer.

### CROSS-REFERENCE TO RELATED APPLICATION

This application is based on and claims priority to and the benefit of Korean Patent Application No. 10-2025-0049255, filed on Apr. 16, 2025 in the Korean Intellectual Property Office, the disclosure of which is herein incorporated by reference in its entirety.

### BACKGROUND

### 1. Field

The present disclosure relates to a display device and an electronic device including the display device.

### 2. Description of Related Art

Electronic devices that provide images to a user, such as a smart phone, a digital camera, a notebook computer, a navigation unit, and a smart television, include a display device to display the images. The display device generates the images and provides the images to the user through a display screen thereof.

In recent years, with the technological development for the display device, various types of display devices have been developed. For example, various flexible display devices, which are foldable, rollable, or capable of being transformed into a curved shape, are being developed. The flexible display devices are easy to carry and improve user convenience. Among the flexible display devices, a foldable display device is folded about a folding axis extending in one direction. The foldable display device is folded or unfolded around the folding axis.

The display device includes a display panel that displays the images, an input sensing part disposed on the display panel to sense an input by a user’s touch, and a digitizer disposed under the display panel to sense an input by a pen. When the digitizer is separately disposed under the display panel, a separate electromagnetic shielding layer is required to shield electromagnetic waves that affect an operation of the digitizer. This results in an increase in a thickness of the display device.

### SUMMARY

The present disclosure provides a display device with reduced thickness and improved surface quality and an electronic device including the display device.

Embodiments of the inventive concept provide a display device including a display panel including a folding area; an input sensing part on the display panel, configured to sense a first input generated by a user’s touch and a second input generated by a pen; a barrier layer under the display panel; an electromagnetic shielding layer under the barrier layer; a first adhesive layer between the barrier layer and the electromagnetic shielding layer; and a first planarization layer between the first adhesive layer and the electromagnetic shielding layer.

Embodiments of the inventive concept provide a display device including a display panel including a folding area; an input sensing part on the display panel, configured to sense a first input generated by a user’s touch and a second input generated by a pen; an electromagnetic shielding layer under the display panel; a support plate under the electromagnetic shielding layer, including a plurality of lattice openings defined therethrough and overlapping the folding area; a first planarization layer between the display panel and the electromagnetic shielding layer; and a second planarization layer between the support plate and the electromagnetic shielding layer. The first and second planarization layers each have a modulus smaller than a modulus of the electromagnetic shielding layer. The first and second planarization layers each have a thickness smaller than a thickness of the electromagnetic shielding layer.

Embodiments of the inventive concept provide an electronic device including at least one processor and a display device configured to receive an image signal from the at least one processor and provide an image corresponding to the image signal. The display device includes a display panel including a folding area; an input sensing part on the display panel, configured to sense a first input generated by a user’s touch and a second input generated by a pen; a barrier layer under the display panel; an electromagnetic shielding layer under the barrier layer; a first adhesive layer between the barrier layer and the electromagnetic shielding layer; and a first planarization layer between the first adhesive layer and the electromagnetic shielding layer.

### BRIEF DESCRIPTION OF DRAWINGS

The above and other aspects, features, and advantages of specific embodiments of the present disclosure will be more apparent from the following description with reference to the accompanying drawings.

FIG. 1 is a block diagram of an electronic device according to one or more embodiments of the present disclosure;

FIG. 2 is a schematic view of electronic devices according to one or more embodiments of the present disclosure;

FIG. 3 is a perspective view of an electronic device according to one or more embodiments of the present disclosure;

FIG. 4 is a view illustrating a folded state of the electronic device shown in FIG. 3;

FIG. 5 is an exploded perspective view of the electronic device shown in FIG. 3;

FIG. 6 is a cross-sectional view of an electronic panel including a display panel shown in FIG. 5;

FIG. 7 is a cross-sectional view of the display panel shown in FIG. 6;

FIG. 8 is a plan view of a display panel shown in FIG. 5;

FIG. 9 is a cross-sectional view of an electronic panel corresponding to one pixel included in the display panel in FIG. 8;

FIG. 10 is a plan view of an input sensing part shown in FIG. 6;

FIG. 11 is an enlarged view of a first area A1 shown in FIG. 10;

FIG. 12 is a view of a configuration of a first pen sensing electrode and a first-second pen sensing electrode shown in FIG. 11;

FIG. 13A is a cross-sectional view taken along a line X-X’ of FIG. 11;

FIG. 13B is a cross-sectional view taken along a line Y-Y’ of FIG. 11;

FIGS. 14A-14C are views illustrating an operation of pen sensing electrodes shown in FIG. 10;

FIG. 15 is a view illustrating a charging operation of a pen located above an input sensing part;

FIG. 16 is a view illustrating a sensing operation for a touch by the pen shown in FIG. 15;

FIG. 17 is a cross-sectional view of a display device taken along a line I-I’ of FIG. 8;

FIG. 18 is a perspective view of a support plate shown in FIG. 17;

FIG. 19 is an enlarged plan view of a second area A2 shown in FIG. 18;

FIG. 20 is a view illustrating a folded state of a display device shown in FIG. 17;

FIG. 21 is a diagram illustrating results of measuring flatness of a shielding layer without a planarization layer, a shielding layer with a planarization layer, a display module including a shielding layer without a planarization layer, and a display module including a shielding layer with a planarization layer;

FIG. 22 is a cross-sectional view of a display device according to one or more embodiments of the present disclosure;

FIGS. 23 and 24 are diagrams illustrating a manufacturing method of providing a first planarization layer on an upper surface of a shielding layer according to one or more embodiments of the present disclosure;

FIG. 25 is a diagram illustrating a first planarization layer according to one or more embodiments of the present disclosure; and

FIGS. 26-28 are cross-sectional views of display devices according to various embodiments of the present disclosure.

### DETAILED DESCRIPTION

In the present disclosure, it is to be understood that when an element (or area, layer, or portion) is referred to as being "on", "connected to" or "coupled to" another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It is to be understood that, although the terms first, second, etc. may be used herein to describe various elements, these elements are not limited by these terms. These terms are only used to distinguish one element from another element. Thus, a first element discussed below could be termed a second element without departing from the teachings of the present disclosure. As an example, without departing from the scope of the present disclosure, a first component, a first part, a first region, a first layer, and a first portion are referred to as a second component, a second part, a second region, a second layer, and a second portion, respectively, and vice versa. As used herein, the singular forms, “a”, “an” and “the” are intended to include the plural forms as well, unless the context clearly indicates otherwise.

Spatially relative terms, such as “below”, “lower”, “above”, “upper” and the like, may be used herein for ease of description to describe one element or feature’s relationship to another elements or features as shown in the figures.

It is to be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It is to be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments of the present disclosure will be described with reference to accompanying drawings.

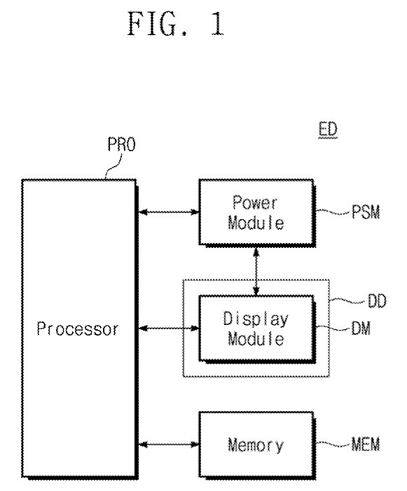

FIG. 1 is a block diagram of the electronic device according to one or more embodiments of the present disclosure.

Referring to FIG. 1, an electronic device ED according to one or more embodiments of the present disclosure may include a display device DD and may further include modules or devices having additional functions in addition to the display device DD. The electronic device ED may include a display module DM, at least one processor PRO, a memory MEM, and a power module PSM, and the display device DD may include the display module DM.

The processor PRO may include, for example but not limited to, at least one of a central processing unit (CPU), an application processor (AP), a graphics processing unit (GPU), a communication processor (CP), an image signal processor (ISP), and a controller.

The processor PRO may process an image signal and provide the processed image signal to the display device DD. The display device DD may receive the image signal from the processor PRO and may display an image corresponding to the image signal to a user.

The processor PRO may be electrically connected to the display module DM of the display device DD via a flexible printed circuit board, a connector, and the like. The display module DM may display images based on data received from the processor PRO.

In an embodiment, the processor PRO may include two or more components from a functional or structural perspective. For example, the processor PRO may include a main processor in a form of a first driving chip that includes the central processing unit and an auxiliary processor in a form of a second driving chip that includes the controller configured to receive an image signal from the main processor and to process the image signal according to an interface specification of the display module DM.

The memory MEM may store data information related to an operation of the processor PRO and/or the display module DM. When the processor PRO executes an application stored in the memory MEM, an image signal and/or an input control signal may be transmitted to the display module DM, and the display module DM may process the received signal to output image information through a display screen.

The power module PSM may include a power supply module, such as a power adapter or a battery device, and a power conversion module that converts power supplied by the power supply module to generate power required for the operation of the electronic device ED.

At least one of components of the electronic device ED may be included in the display device DD. In addition, among individual modules that are functionally included within a single module, at least one module may be included in the display device DD while at least another module may be provided separately from the display device DD. As an example, the display device DD may include the display module DM, while the processor PRO, the memory MEM, and the power module PSM may be provided as separate devices within the electronic device ED without being included in the display device DD.

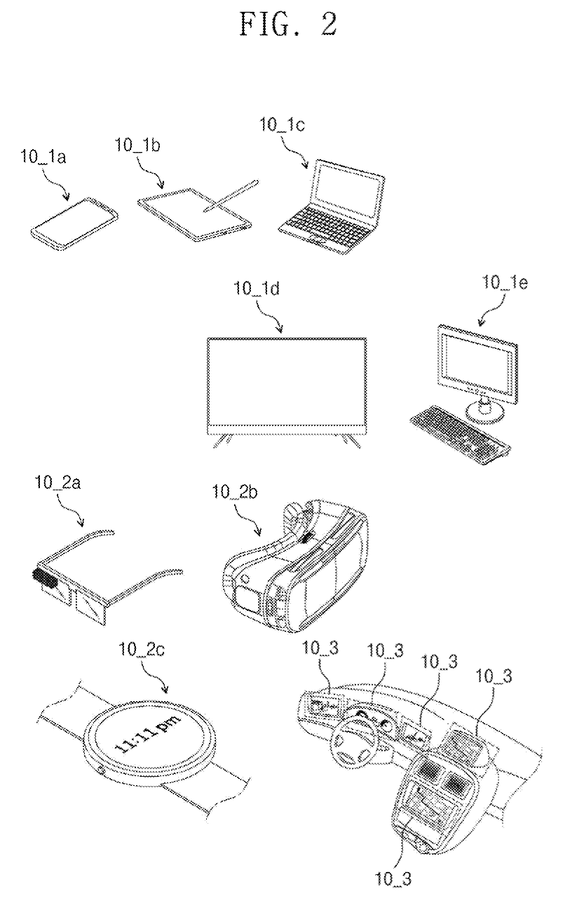

FIG. 2 is a schematic view of various electronic devices according to one or more embodiments of the present disclosure.

Referring to FIG. 2, the display device DD according to one or more embodiments of the present disclosure may be applied to various electronic devices. As an example, various electronic devices to which the display device DD according to embodiments is applied may include an electronic device to display images, such as a smartphone 10_1a, a tablet PC 10_1b, a laptop computer 10_1c, a television 10_1d, a desktop monitor 10_1e, etc.

In addition, various electronic devices to which the display device DD according to one or more embodiments is applied may include wearable electronic devices, such as a smart glasses 10_2a, a head-mounted display 10_2b, a smartwatch 10_2c, etc. Further, various electronic devices to which the display device DD according to one or more embodiments is applied may include an in-vehicle electronic device 10_3, such as an instrument panel, a center fascia, a dashboard-mounted center information display (CID), or a room mirror display.

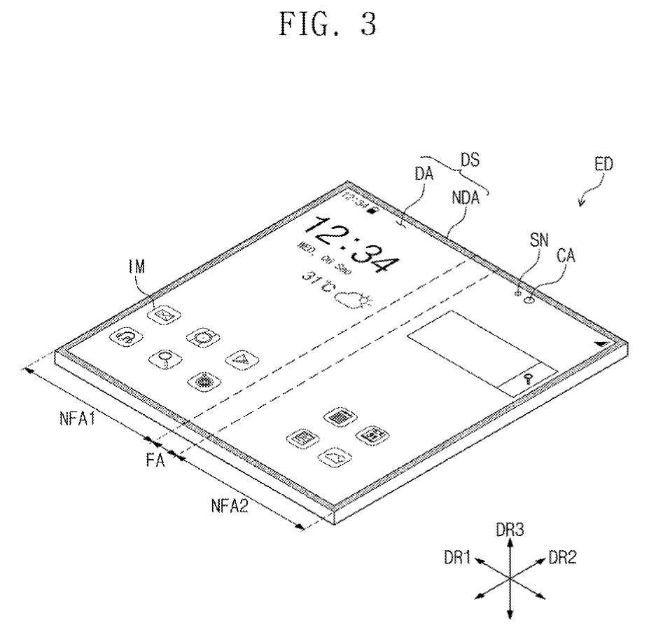

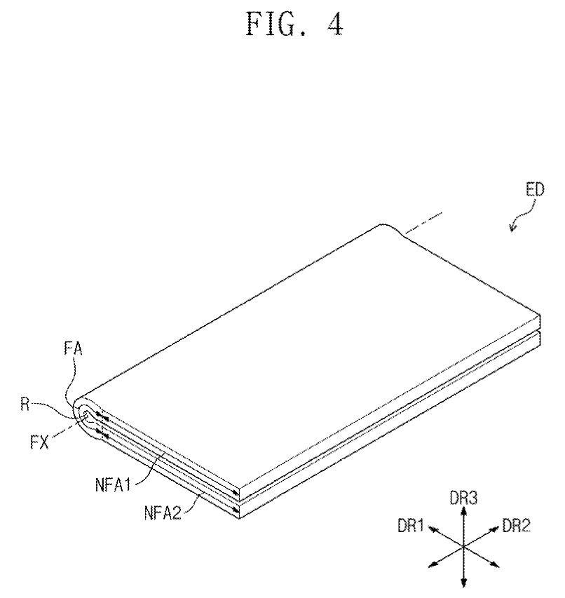

FIG. 3 is a perspective view of the electronic device according to one or more embodiments of the present disclosure. FIG. 4 is a view illustrating a folded state of the electronic device shown in FIG. 3.

As an example, the electronic device ED shown in FIGS. 3 and 4 may be a foldable smartphone.

Referring to FIG. 3, the electronic device ED may include a plane defined by a first direction DR1 and a second direction DR2 intersecting the first direction DR1. When viewed in a plane, the electronic device ED may have a quadrangular shape. However, the shape of the electronic device ED is not limited to the rectangular shape, and the electronic device ED may have various shapes, such as a circular shape and a polygonal shape. The electronic device ED may be a flexible electronic device.

Hereinafter, a direction substantially perpendicular to the plane defined by the first direction DR1 and the second direction DR2 may be referred to as a third direction DR3. In the present disclosure, the expression “when viewed in a plane” may mean a state of being viewed in the third direction DR3.

The electronic device ED may include a folding area FA and a plurality of non-folding areas NFA1 and NFA2. The non-folding areas NFA1 and NFA2 may include a first non-folding area NFA1 and a second non-folding area NFA2. The folding area FA may be disposed between the first non-folding area NFA1 and the second non-folding area NFA2. The first non-folding area NFA1, the folding area FA, and the second non-folding area NFA2 may be arranged in the first direction DR1.

In the present embodiment, one folding area FA and two non-folding areas NFA1 and NFA2 are shown as a representative example, however, a number of the folding areas FA and a number of non-folding areas NFA1 and NFA2 is not limited thereto or thereby. For example, the electronic device ED may include more than two non-folding areas and a plurality of folding areas disposed between the non-folding areas.

An upper surface of the electronic device ED may be referred to as a display surface DS, and the display surface DS may be a plane defined by the first direction DR1 and the second direction DR2. An image IM generated by the electronic device ED may be provided to a user through the display surface DS.

The display surface DS may include a display area DA and a non-display area NDA around the display area DA. The display area DA may display the image, and the non-display area NDA may not display the image. The non-display area NDA may surround the display area DA and may define an edge of the electronic device ED, which may be printed by a predetermined color.

The electronic device ED may include at least one sensor SN and at least one camera CA. The at least one sensor SN and the at least one camera CA may be disposed adjacent to the edge of the electronic device ED. The at least one sensor SN and the at least one camera CA may be disposed in the display area DA adjacent to the non-display area NDA. The at least one sensor SN and the at least one camera CA may be disposed in the second non-folding area NFA2, however, according to an embodiment, the at least one sensor SN and the at least one camera CA may be disposed in the first non-folding area NFA1.

A light may be provided to the at least one camera CA and the at least one sensor SN after passing through portions of the electronic device ED on which the at least one sensor SN and the at least one camera CA are disposed. As an example, the at least one sensor SN may include a proximity illumination sensor, however, the at least one sensor SN is not limited. The at least one camera CA may take a picture of an external object. One or more of the at least one sensor SN and the at least one camera CA may be provided in plural.

The electronic device ED may sense an input applied from outside the electronic device ED. For example, the electronic device ED may sense a first input by a user’s touch and/or a second input by a pen (not shown).

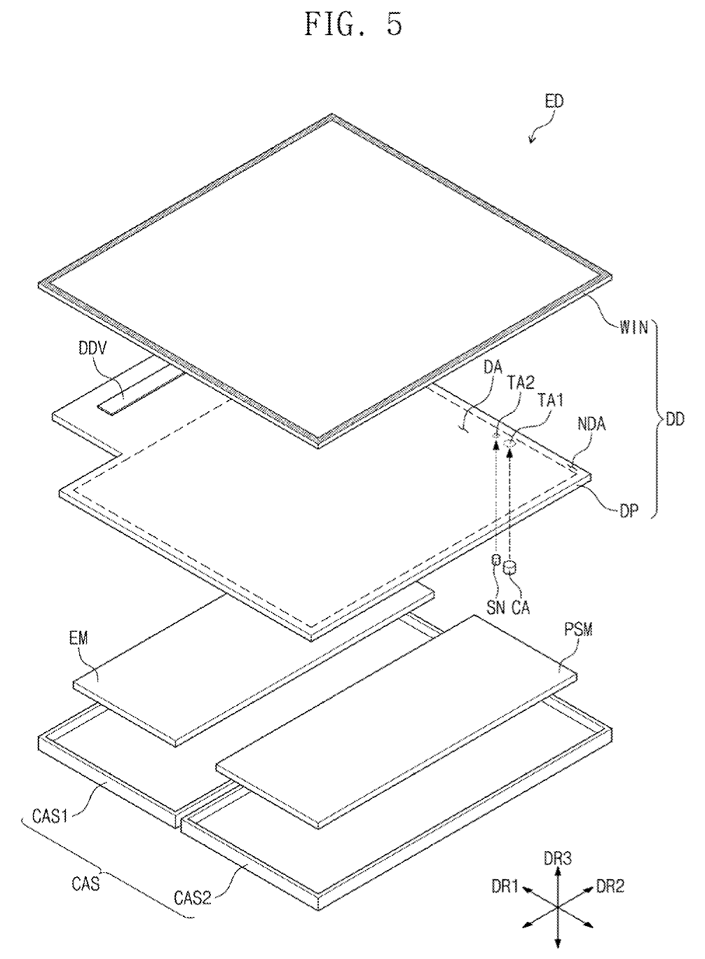

Referring to FIG. 4, the electronic device ED may be a foldable electronic device ED that is folded or unfolded. The folding area FA may be folded with respect to a folding axis FX (refer to FIG. 5) substantially parallel to the second direction DR2, and thus, the electronic device ED may be folded.

When the electronic device ED is folded, the first non-folding area NFA1 and the second non-folding area NFA2 may face each other, and thus, the electronic device ED may be inwardly folded (in-folding) such that the display surface DS is not exposed to the outside, however, the present disclosure is not limited thereto or thereby. As an example, the electronic device ED may be outwardly folded (out-folding) with respect to the folding axis FX such that the display surface DS is exposed to the outside.

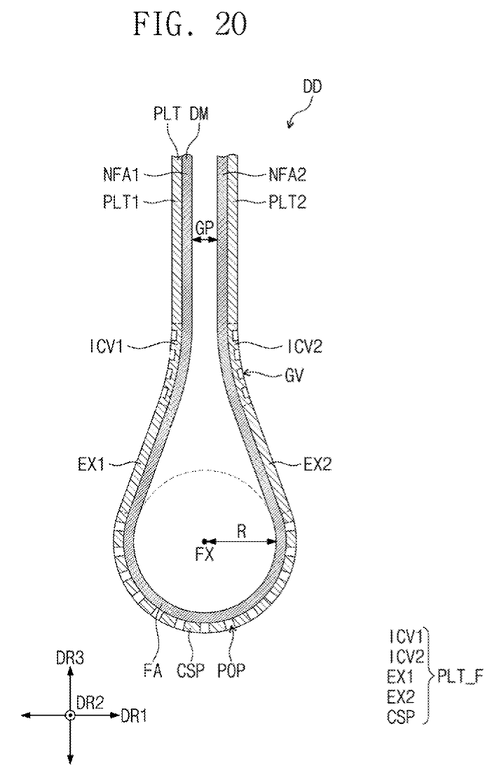

A distance between the first non-folding area NFA1 and the second non-folding area NFA2 may be smaller than a diameter of a circle defined by a radius of curvature R of the folding area FA. In this case, the folding area FA may be folded to have a dumbbell shape (e.g., refer to FIG. 20), and the distance between the first non-folding area NFA1 and the second non-folding area NFA2 may be reduced.

FIG. 5 is an exploded perspective view of the electronic device shown in FIG. 3.

Referring to FIG. 5, the electronic device ED may include the display device DD, the camera CA, the sensor SN, an electronic module EM, the power module PSM, and a case CAS.

The display device DD may include a window WIN and a display panel DP. As an example, FIG. 5 shows the window WIN and the display panel DP among components of the display device DD, however, the display device DD may further include various components in addition to the window WIN and the display panel DP. A detailed stack structure of the display device DD will be described later.

The window WIN may be disposed on the display panel DP and may protect the display panel DP. The window WIN may transmit a light generated by the display panel DP to provide the light to a user.

The display panel DP may include a display area DA and a non-display area NDA, which respectively correspond to the display area DA (refer to FIG. 3) and the non-display area NDA (refer to FIG. 3) of the electronic device ED. A first transmission area TA1 and a second transmission area TA2 may be defined in the display panel DP. The first transmission area TA1 and the second transmission area TA2 may have higher light transmittance than surrounding areas. The camera CA may be disposed under the first transmission area TA1, and the sensor SN may be disposed under the second transmission area TA2. The light transmitted through the first and second transmission areas TA1 and TA2 may be provided to the camera CA and the sensor SN.

The display device DD may include a data driver DDV disposed in the non-display area NDA of the display panel DP. The data driver DDV may be manufactured in an integrated circuit chip form and may be mounted on the non-display area NDA, however, the present disclosure is not limited thereto or thereby. According to an embodiment, the data driver DDV may be mounted on a flexible circuit board connected to the display panel DP.

The electronic module EM and the power module PSM may be disposed under the display device DD. Although not shown in figures, the electronic module EM and the power module PSM may be connected to each other via a separate flexible circuit board. The electronic module EM may control an operation of the display device DD. The power module PSM may supply a power to the electronic module EM. The electronic module EM may include the processor PRO.

The case CAS may accommodate the display device DD, the electronic module EM, and the power module PSM. The case CAS may include two cases, e.g., first and second cases CAS1 and CAS2, that are used to fold the display device DD. The first and second cases CAS1 and CAS2 may extend in the second direction DR2 and may be arranged in the first direction DR1.

Although not shown in figures, the electronic device ED may further include a hinge structure to connect the first and second cases CAS1 and CAS2 and to rotate the first and second cases CAS1 and CAS2 such that the electronic device ED is folded. The case CAS may protect the display device DD, the electronic module EM, and the power module PSM.

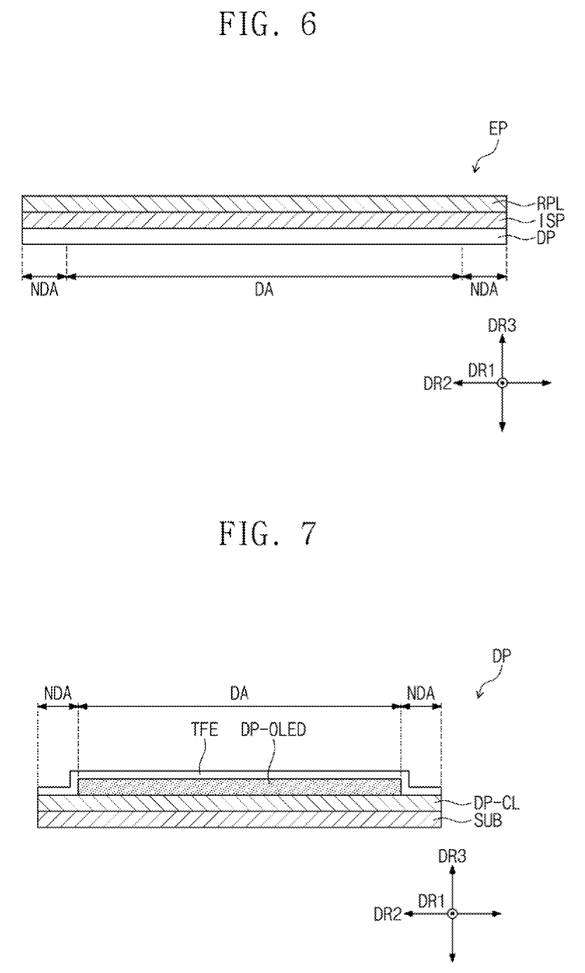

FIG. 6 is a cross-sectional view of an electronic panel including the display panel shown in FIG. 5. FIG. 7 is a cross-sectional view of the display panel shown in FIG. 6.

As an example, FIGS. 6 and 7 show the cross-section when viewed in the first direction DR1.

Referring to FIG. 6, the electronic panel EP may include the display panel DP, an input sensing part ISP disposed on the display panel DP, and an anti-reflective layer RPL disposed on the input sensing part ISP. The display device DD described above may include the electronic panel EP.

The display panel DP may be a flexible display panel. According to an embodiment, the display panel DP may be a light emitting type display panel. As an example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot or a quantum rod. Hereinafter, the organic light emitting display panel will be described as a representative example of the display panel DP for illustrative purposes, however, the present disclosure is not limited thereto or thereby.

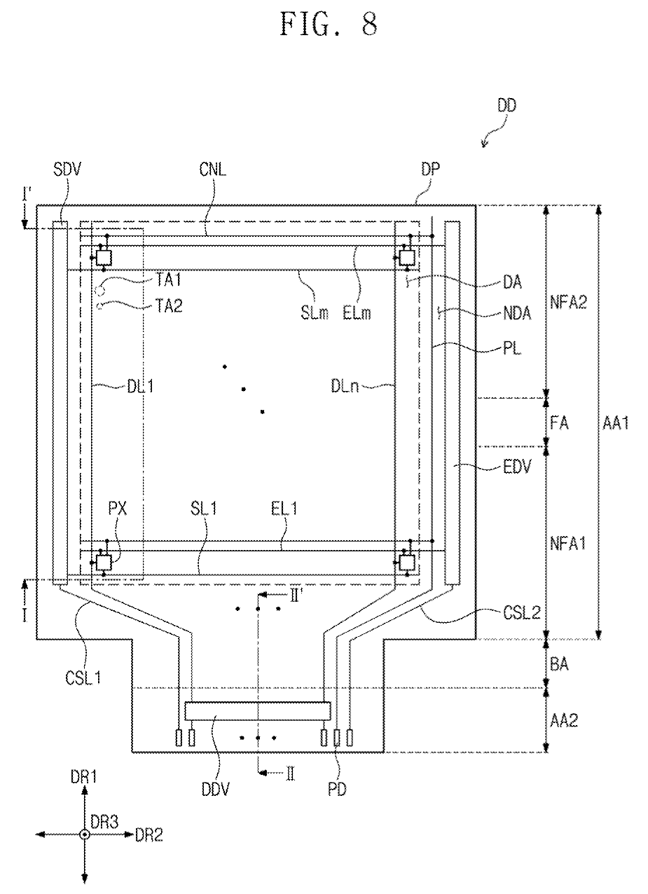

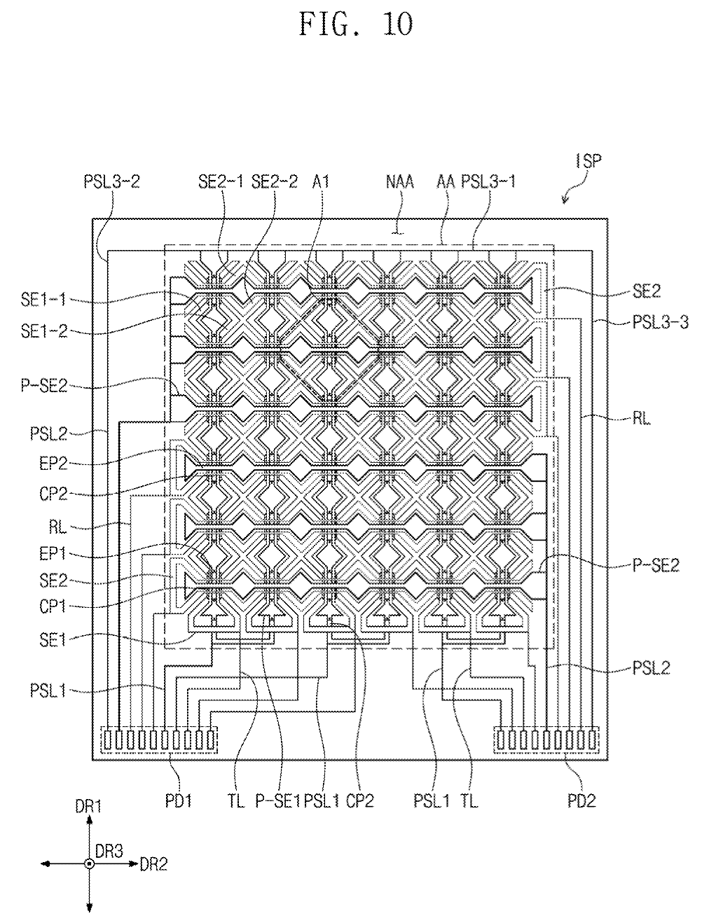

The input sensing part ISP may include a plurality of sensing electrodes (shown in FIG. 8) to sense a first input by a capacitive manner. The input sensing part ISP may include a plurality of pen sensing electrodes to sense a second input by an electromagnetic manner. The input sensing part ISP will be described in detail later with reference to FIG. 10. The input sensing part ISP may be directly formed on the display panel DP when the electronic panel EP is manufactured.

The anti-reflective layer RPL may be directly formed on the input sensing part ISP when the electronic panel EP is manufactured, however, the present disclosure is not limited thereto or thereby. As an example, the anti-reflective layer RPL may be attached to the input sensing part ISP by an adhesive layer after being manufactured as a separate panel.

The anti-reflective layer RPL may be defined as an external light reflection prevention film. The anti-reflective layer RPL may reduce a reflectance of an external light incident to the display panel DP from above of the electronic device ED.

Referring to FIG. 7, the display panel DP may include a substrate SUB, a circuit element layer DP-CL disposed on the substrate SUB, a display element layer DP-OLED disposed on the circuit element layer DP-CL, and a thin film encapsulation layer TFE disposed on the display element layer DP-OLED.

The substrate SUB may include a display area DA and a non-display area NDA around the display area DA. The substrate SUB may include a glass material or a flexible plastic material such as polyimide (PI). The display element layer DP-OLED may be disposed in the display area DA.

A plurality of pixels may be arranged in the circuit element layer DP-CL and the display element layer DP-OLED. Each pixel may include transistors arranged in the circuit element layer DP-CL and a light emitting element arranged in the display element layer DP-OLED and connected to the transistors.

The thin film encapsulation layer TFE may be disposed on the circuit element layer DP-CL to cover the display element layer DP-OLED. The thin film encapsulation layer TFE may protect the pixels from moisture, oxygen, and a foreign substance.

FIG. 8 is a plan view of the display panel shown in FIG. 5.

Referring to FIG. 8, the display device DD may include the display panel DP, a scan driver SDV, a data driver DDV, and an emission driver EDV.

The display panel DP may include a first area AA1, a second area AA2, and a bending area BA between the first area AA1 and the second area AA2. The first area AA1, the bending area BA, and the second area AA2 may be arranged in the first direction DR1.

The first area AA1 may include the display area DA and the non-display area NDA around the display area DA. The non-display area NDA may surround the display area DA. The display area DA may be an area in which an image is displayed, and the non-display area NDA may be an area in which an image is not displayed. The second area AA2 and the bending area BA may be areas in which an image is not displayed.

When viewed in the second direction DR2, the first area AA1 may include a first non-folding area NFA1, a second non-folding area NFA2, and a folding area FA between the first non-folding area NFA1 and the second non-folding area NFA2. The first and second non-folding areas NFA1 and NFA2 and the folding area FA may respectively correspond to the first and second non-folding areas NFA1 and NFA2 and the folding area FA of the electronic device ED shown in FIG. 3. The first and second transmission areas TA1 and TA2 may be defined in the display area DA and the second non-folding area NFA2.

The first area AA1 may be folded with respect to the folding axis FX. As an example, since the folding area FA of the first area AA1 is folded with respect to the folding axis FX, the display panel DP may be folded.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, a power line PL, a plurality of connection lines CNL, and a plurality of pads PD. Each of “m” and “n” is a natural number. The pixels PX may be arranged in the display area DA and may be connected to the scan lines SL1 to SLm, the data lines DL1 to DLn, and the emission lines EL1 to ELm.

The scan driver SDV and the emission driver EDV may be disposed in the non-display area NDA. The scan driver SDV and the emission driver EDV may be disposed in the non-display area NDA to be respectively adjacent to both side portions of the first area AA1, which are opposite to each other in the second direction DR2. The data driver DDV may be disposed in the second area AA2. The data driver DDV may be manufactured in an integrated circuit chip form and may be mounted on the second area AA2.

The scan lines SL1 to SLm may extend in the second direction DR2 and may be connected to the scan driver SDV. The data lines DL1 to DLn may extend in the first direction DR1 and may be connected to the data driver DDV via the bending area BA. The data driver DDV may be connected to the pixels PX via the data lines DL1 to DLn. The emission lines EL1 to ELm may extend in the second direction DR2 and may be connected to the emission driver EDV.

The power line PL may extend in the first direction DR1 and may be disposed in the non-display area NDA. The power line PL may be disposed between the display area DA and the emission driver EDV. The power line PL may extend to the second area AA2 via the bending area BA. When viewed in the plane, the power line PL may extend toward a lower end portion of the second area AA2. The power line PL may receive a driving voltage.

The connection lines CNL may extend in the second direction DR2 and may be arranged in the first direction DR1. The connection lines CNL may be connected to the power line PL and the pixels PX. The driving voltage may be applied to the pixels PX via the power line PL and the connection lines CNL connected to the power line PL.

The first control line CSL1 may be connected to the scan driver SDV and may extend toward the lower end portion of the second area AA2 via the bending area BA. The second control line CSL2 may be connected to the emission driver EDV and may extend toward the lower end portion of the second area AA2 via the bending area BA. The data driver DDV may be disposed between the first control line CSL1 and the second control line CSL2.

When viewed in the plane, the pads PD may be arranged adjacent to the lower end portion of the second area AA2. The data driver DDV, the power line PL, the first control line CSL1, and the second control line CSL2 may be connected to the pads PD.

The data lines DL1 to DLn may be connected to corresponding pads PD via the data driver DDV. As an example, the data lines DL1 to DLn may be connected to the data driver DDV, and the data driver DDV may be connected to the pads PD corresponding to the data lines DL1 to DLn.

Although not shown in figures, the pads PD may be connected to a printed circuit board, and a timing controller and a voltage generator may be disposed on the printed circuit board. The timing controller may be manufactured in an integrated circuit chip and may be mounted on the printed circuit board. The timing controller and the voltage generator may be connected to the pads PD through the printed circuit board.

The timing controller may control operations of the scan driver SDV, the data driver DDV, and the emission driver EDV. The timing controller may generate a scan control signal, a data control signal, and an emission control signal in response to control signals applied from an outside. The voltage generator may generate the driving voltage.

The scan control signal may be applied to the scan driver SDV via the first control line CSL1. The emission control signal may be applied to the emission driver EDV via the second control line CSL2. The data control signal may be applied to the data driver DDV. The timing controller may receive an image signal from the outside, may convert a data format of the image signal to a data format appropriate to an interface between the timing controller and the data driver DDV, and may provide the converted image signal to the data driver DDV.

The scan driver SDV may generate a plurality of scan signals in response to the scan control signal. The scan signals may be applied to the pixels PX via the scan lines SL1 to SLm. The scan signals may be sequentially applied to the pixels PX.

The data driver DDV may generate a plurality of data voltages corresponding to the image signals in response to the data control signal. The data voltages may be applied to the pixels PX via the data lines DL1 to DLn. The emission driver EDV may generate a plurality of emission signals in response to the emission control signal. The emission signals may be applied to the pixels PX via the emission lines EL1 to ELm.

The pixels PX may receive the data voltages in response to the scan signals. The pixels PX may emit a light having a luminance corresponding to the data voltages in response to the emission signals, and thus, an image may be displayed. An emission time of the pixels PX may be controlled by the emission signals.

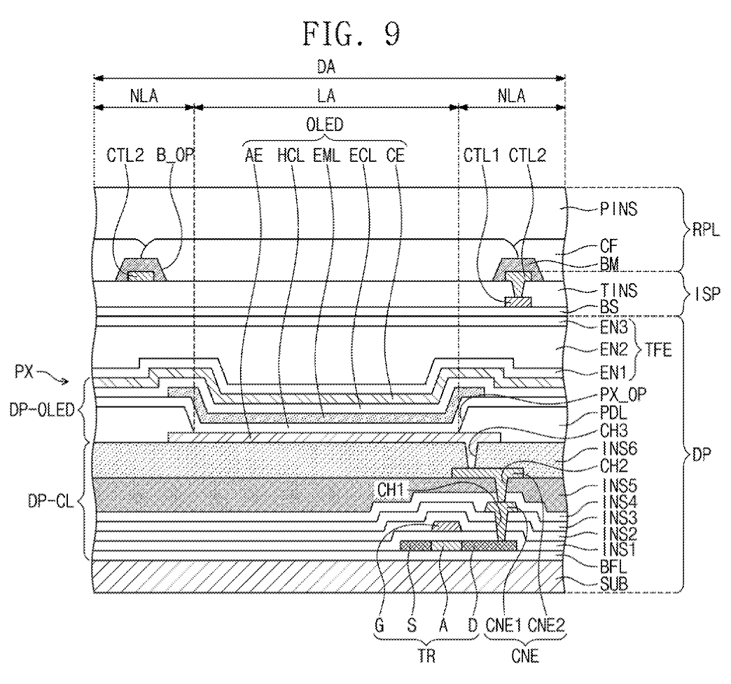

FIG. 9 is a cross-sectional view of the electronic panel corresponding to one pixel included in the display panel shown in FIG. 8.

Referring to FIG. 9, the display panel DP may include the pixel PX, and the pixel PX may include a transistor TR and a light emitting element OLED. The light emitting element OLED may include a first electrode (or an anode) AE, a second electrode (or a cathode) CE, a hole control layer HCL, an electron control layer ECL, and a light emitting layer EML.

The transistor TR and the light emitting element OLED may be disposed on the substrate SUB. As an example, one transistor TR is shown in FIG. 9 as a representative example, however, the pixel PX may include a plurality of transistors and at least one capacitor to drive the light emitting element OLED.

The display area DA may include a light emitting area LA corresponding to each pixel PX and a non-light-emitting area NLA around the light emitting area LA. The light emitting element OLED may be disposed in the light emitting area LA.

A buffer layer BFL may be disposed on the substrate SUB, and the buffer layer BFL may be an inorganic layer. A semiconductor pattern may be disposed on the buffer layer BFL. The semiconductor pattern may include polycrystalline silicon, amorphous silicon, or metal oxide.

The semiconductor pattern may be doped with an N-type dopant or a P-type dopant. The semiconductor pattern may include a high-doped region and a low-doped region. The high-doped region may have a conductivity greater than that of the low-doped region and may substantially serve as a source electrode and a drain electrode of the transistor TR. The low-doped region may substantially correspond to an active (or a channel) of the transistor TR.

A source S, an active A, and a drain D of the transistor TR may be formed from the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

A connection electrode CNE may include a first connection electrode CNE1 and a second connection electrode CNE2 to connect the transistor TR to the light emitting element OLED. The first connection electrode CNE1 may be disposed on the third insulating layer INS3 and may be connected to the drain D via a first contact hole CH1 defined in the first, second, and third insulating layers INS1, INS2, and INS3.

A fourth insulating layer INS4 may be disposed on the first connection electrode CNE1. A fifth insulating layer INS5 may be disposed on the fourth insulating layer INS4. The second connection electrode CNE2 may be disposed on the fifth insulating layer INS5. The second connection electrode CNE2 may be connected to the first connection electrode CNE1 via a second contact hole CH2 defined in the fourth insulating layer INS4 and the fifth insulating layer INS5.

A sixth insulating layer INS6 may be disposed on the second connection electrode CNE2. A stack of layers from the buffer layer BFL to the sixth insulating layer INS6 may collectively be defined as the circuit element layer DP-CL. Each of the first to sixth insulating layers INS1 to INS6 may be an inorganic layer or an organic layer.

The first electrode AE may be disposed on the sixth insulating layer INS6. The first electrode AE may be connected to the second connection electrode CNE2 via a third contact hole CH3 defined in the sixth insulating layer INS6. A pixel definition layer PDL may be disposed on the first electrode AE and the sixth insulating layer INS6. An opening PX_OP may be defined in the pixel definition layer PDL to expose a portion of the first electrode AE.

The hole control layer HCL may be disposed on the first electrode AE and the pixel definition layer PDL. The hole control layer HCL may include a hole transport layer and a hole injection layer.

The light emitting layer EML may be disposed on the hole control layer HCL. The light emitting layer EML may be disposed in an area corresponding to the opening PX_OP. The light emitting layer EML may include an organic material and/or an inorganic material. The light emitting layer EML may generate a light having one of red, green, and blue colors.

The electron control layer ECL may be disposed on the light emitting layer EML and the hole control layer HCL. The electron control layer ECL may include an electron transport layer and an electron injection layer. The hole control layer HCL and the electron control layer ECL may be commonly disposed in the light emitting area LA and the non-light-emitting area NLA.

The second electrode CE may be disposed on the electron control layer ECL. The second electrode CE may be commonly disposed over the pixels PX. A layer in which the light emitting element OLED is disposed may be referred to as the display element layer DP-OLED.

A thin film encapsulation layer TFE may be disposed on the second electrode CE to cover the pixel PX. The thin film encapsulation layer TFE may include a first encapsulation layer EN1 disposed on the second electrode CE, a second encapsulation layer EN2 disposed on the first encapsulation layer EN1, and a third encapsulation layer EN3 disposed on the second encapsulation layer EN2.

The first and third encapsulation layers EN1 and EN3 may include an inorganic insulating layer and may protect the pixel PX from moisture and oxygen. The second encapsulation layer EN2 may include an organic insulating layer and may protect the pixel PX from a foreign substance such as dust particles.

A first voltage may be applied to the first electrode AE via the transistor TR, and a second voltage having a voltage level lower than that of the first voltage may be applied to the second electrode CE. Holes and electrons injected into the light emitting layer EML may be recombined to generate excitons, and the light emitting element OLED may emit a light by the excitons that return to a ground state from an excited state.

A stack of layers from the substrate SUB to the thin film encapsulation layer TFE may collectively be defined as the display panel DP. The input sensing part ISP may be disposed on the thin film encapsulation layer TFE. The input sensing part ISP may be directly manufactured on an upper surface of the thin film encapsulation layer TFE.

A base layer BS may be disposed on the thin film encapsulation layer TFE. The base layer BS may include an inorganic insulating layer. At least one inorganic insulating layer may be provided on the thin film encapsulation layer TFE as the base layer BS.

The input sensing part ISP may include a first conductive pattern CTL1 and a second conductive pattern CTL2 disposed on the first conductive pattern CTL1. The first conductive pattern CTL1 may be disposed on the base layer BS. An insulating layer TINS may be disposed on the base layer BS to cover the first conductive pattern CTL1. The insulating layer TINS may include an inorganic insulating layer or an organic insulating layer. The second conductive pattern CTL2 may be disposed on the insulating layer TINS.

The first and second conductive patterns CTL1 and CTL2 may overlap the non-light-emitting area NLA. Although not shown in figures, the first and second conductive patterns CTL1 and CTL2 may be disposed in the non-light-emitting area NLA between the light emitting areas LA and may have a mesh shape.

The first and second conductive patterns CTL1 and CTL2 may form the sensing electrodes and the pen sensing electrodes of the input sensing part ISP. As an example, the first and second conductive patterns CTL1 and CTL2 having the mesh shape may be separated from each other in a selected area to form the sensing electrodes and the pen sensing electrodes. A portion of the second conductive pattern CTL2 may be connected to the first conductive pattern CTL1.

The anti-reflective layer RPL may be disposed on the second conductive pattern CTL2. The anti-reflective layer RPL may include a black matrix BM and a plurality of color filters CF. The black matrix BM may overlap the non-light-emitting area NLA, and the color filters CF may overlap the light emitting areas LA, respectively.

The black matrix BM may be disposed on the insulating layer TINS to cover the second conductive pattern CTL2. An opening B_OP may be defined in the black matrix BM to overlap the light emitting area LA and the opening PX_OP. The black matrix BM may absorb and block the light. A width of the opening B_OP may be greater than a width of the opening PX_OP.

The color filters CF may be disposed on the insulating layer TINS and the black matrix BM. The color filters CF may be disposed in the openings B_OP, respectively. A planarization insulating layer PINS may be disposed on the color filters CF. The planarization insulating layer PINS may provide a flat upper surface.

In a case where the external light incident to the display panel DP is provided to the user after being reflected by the display panel DP, like a mirror, the user may perceive the external light. The anti-reflective layer RPL may include the color filters CF that display the same colors as those of the pixels to prevent the above-mentioned phenomenon. The color filters CF may filter the external light to have the same color as the pixels. In this case, the external light may not be perceived by the user.

However, the present disclosure is not limited thereto or thereby, and the anti-reflective layer RPL may include a polarizing film to reduce the reflectance with respect to the external light. The polarizing film may be attached to the input sensing part ISP by an adhesive layer after being manufactured separately. The polarizing film may include a retarder and/or a polarizer.

FIG. 10 is a plan view of the input sensing part shown in FIG. 6.

Referring to FIG. 10, the input sensing part ISP may include a plurality of sensing electrodes SE1 and SE2, a plurality of sensing lines TL and RL, a plurality of pen sensing electrodes P-SE1 and P-SE2, a plurality of pen sensing lines PSL1, PSL2, and PSL3-1 to PSL3-3, a plurality of first pads PD1, and a plurality of second pads PD2. The sensing electrodes SE1 and SE2, the sensing lines TL and RL, the pen sensing electrodes P-SE1 and P-SE2, the pen sensing lines PSL1, PSL2, and PSL3-1 to PSL3-3, and the first and second pads PD1 and PD2 may be disposed on the thin film encapsulation layer TFE.

A plane area of the input sensing part ISP may include an active area AA and a non-active area NAA around the active area AA. When viewed in the plane, the active area AA may overlap the display area DA, and the non-active area NAA may overlap the non-display area NDA.

The sensing electrodes SE1 and SE2 may be arranged in the active area AA, and the first and second pads PD1 and PD2 may be arranged in the non-active area NAA. The first pads PD1 and the second pads PD2 may be arranged adjacent to a lower end portion of the input sensing part ISP when viewed in the plane. As an example, the first pads PD1 may be arranged adjacent to a left side portion of the input sensing part ISP, and the second pads PD2 may be arranged adjacent to a right side portion of the input sensing part ISP.

The sensing electrodes SE1 and SE2 may include a plurality of first sensing electrodes SE1 extending in the first direction DR1 and arranged in the second direction DR2 and a plurality of second sensing electrodes SE2 extending in the second direction DR2 and arranged in the first direction DR1. The second sensing electrodes SE2 may extend to be insulated from the first sensing electrodes SE1 while crossing the first sensing electrodes SE1. The first and second sensing electrodes SE1 and SE2 may be used to sense the first input.

The sensing lines TL and RL may be connected to one end portions of the first and second sensing electrodes SE1 and SE2, may extend to the non-active area NAA, and may be connected to the first and second pads PD1 and PD2. The sensing lines TL and RL may include a plurality of first sensing lines TL connected to the first sensing electrodes SE1 and a plurality of second sensing lines RL connected to the second sensing electrodes SE2.

The first sensing lines TL may be connected to lower end portions of the first sensing electrodes SE1. The first sensing lines TL may extend to the non-active area NAA and may be connected to corresponding first and second pads PD1 and PD2.

The input sensing part ISP may be divided into a left portion and a right portion with respect to a center thereof in the second direction DR2. The first sensing lines TL connected to the first sensing electrodes SE1 disposed in the left portion may be connected to the corresponding first pads PD1. The first sensing lines TL connected to the first sensing electrodes SE1 disposed in the right portion may be connected to corresponding second pads PD2.

The second sensing lines RL may be connected to left end portions or right end portions of the second sensing electrodes SE2. The second sensing lines RL may extend to the non-active area NAA and may be connected to the corresponding first and second pads PD1 and PD2.

The input sensing part ISP may be divided into a lower portion and an upper portion with respect to a center thereof in the first direction DR1. The second sensing lines RL arranged in the lower portion of the input sensing part ISP may be connected to the left end portions of the second sensing electrodes SE2 arranged in the lower portion of the input sensing part ISP. The second sensing lines RL arranged in the upper portion of the input sensing part ISP may be connected to the right end portions of the second sensing electrodes SE2 arranged in the upper portion of the input sensing part ISP.

The second sensing lines RL arranged in the lower portion of the input sensing part ISP may be connected to the corresponding first pads PD1. The second sensing lines RL arranged in the upper portion of the input sensing part ISP may be connected to the corresponding second pads PD2.

Each of the first sensing electrodes SE1 may include a first-first sensing electrode SE1-1 and a first-second sensing electrode SE1-2, which extend in the first direction DR1 and are spaced apart from each other in the second direction DR2. The first-first sensing electrode SE1-1 and the first-second sensing electrode SE1-2 may be substantially symmetrical with respect to the second direction DR2.

In each of the first sensing electrodes SE1, a lower end portion of the first-first sensing electrode SE1-1 and a lower end portion of the first-second sensing electrode SE1-2 may be connected to a corresponding first sensing line TL among the first sensing lines TL. In each of the first sensing electrodes SE1, an upper end portion of the first-first sensing electrode SE1-1 and an upper end portion of the first-second sensing electrode SE1-2 may not be connected to each other.

Each of the second sensing electrodes SE2 may include a second-first sensing electrode SE2-1 and a second-second sensing electrode SE2-2, which extend in the second direction DR2 and are spaced apart from each other in the first direction DR1. The second-first sensing electrode SE2-1 and the second-second sensing electrode SE2-2 may be substantially symmetrical with respect to the first direction DR1.

In each of the second sensing electrodes SE2 arranged in the lower portion of the input sensing part ISP, a left end portion of the second-first sensing electrode SE2-1 and a left end portion of the second-second sensing electrode SE2-2 may be connected to a corresponding second sensing line RL among the second sensing lines RL. In each of the second sensing electrodes SE2 arranged in the lower portion of the input sensing part ISP, a right end portion of the second-first sensing electrode SE2-1 and a right end portion of the second-second sensing electrode SE2-2 may not be connected to each other.

In each of the second sensing electrodes SE2 arranged in the upper portion of the input sensing part ISP, a right end portion of the second-first sensing electrode SE2-1 and a right end portion of the second-second sensing electrode SE2-2 may be connected to a corresponding second sensing line RL among the second sensing lines RL. In each of the second sensing electrodes SE2 arranged in the upper portion of the input sensing part ISP, a left end portion of the second-first sensing electrode SE2-1 and a left end portion of the second-second sensing electrode SE2-2 may not be connected to each other.

As an example, when viewed in the plane, the first sensing lines TL may be arranged in the non-active area NAA adjacent to a lower side portion of the active area AA. In addition, when viewed in the plane, the second sensing lines RL may be arranged in the non-active area NAA adjacent to left and right side portions of the active area AA.

The pen sensing electrodes P-SE1 and P-SE2 may be arranged in the active area AA. The pen sensing lines PSL1, PSL2, and PSL3-1 to PSL3-3 may be connected to the pen sensing electrodes P-SE1 and P-SE2, may extend to the non-active area, and may be connected to corresponding first and second pads PD1 and PD2.

Although not shown in figures, a sensing integrated circuit (IC) used to control the input sensing part ISP may be connected to the second and third pads PD2 and PD3 via the printed circuit board.

The pen sensing electrodes P-SE1 and P-SE2 may include a plurality of first pen sensing electrodes P-SE1 extending in the first direction DR1 and arranged in the second direction DR2 and a plurality of second pen sensing electrodes P-SE2 extending in the second direction DR2 and arranged in the first direction DR1. The first and second pen sensing electrodes P-SE1 and P-SE2 may be used to sense the second input.

The second pen sensing electrodes P-SE2 may extend to cross the first pen sensing electrodes P-SE1 and may be insulated from the first pen sensing electrodes P-SE1. The first pen sensing electrodes P-SE1 may extend to cross the second sensing electrodes SE2 and may be insulated from the second sensing electrodes SE2. The second pen sensing electrodes P-SE2 may extend to cross the first sensing electrodes SE1 and may be insulated from the first sensing electrodes SE1.

Each of the first pen sensing electrodes P-SE1 may be disposed between the first-first sensing electrode SE1-1 and the first-second sensing electrode SE1-2 of a corresponding first sensing electrode SE1 among the first sensing electrodes SE1. Each of the second pen sensing electrodes P-SE2 may be disposed between the second-first sensing electrode SE2-1 and the second-second sensing electrode SE2-2 of a corresponding second sensing electrode SE2 among the second sensing electrodes SE2.

The first pen sensing electrodes P-SE1 and the first sensing electrodes SE1 may be disposed on the same layer. The second pen sensing electrodes P-SE2 and the second sensing electrodes SE2 may be disposed on the same layer. The first pen sensing electrodes P-SE1, the first sensing electrodes SE1, the second pen sensing electrodes P-SE2, and the second sensing electrodes SE2 may be disposed on the same layer.

Upper end portions of the first pen sensing electrodes P-SE1 may be connected to each other. Lower end portions of the first pen sensing electrodes P-SE1 may be connected to each other in pairs. Left end portions of the second pen sensing electrodes P-SE2, which are disposed at the upper portion of the input sensing part ISP, may be connected to each other. Right end portions of the second pen sensing electrodes P-SE2, which are disposed at the lower portion of the input sensing part ISP, may be connected to each other.

Right end portions of the second pen sensing electrodes P-SE2, which are disposed at the upper portion of the input sensing part ISP, may not be connected to each other. Left end portions of the second pen sensing electrodes P-SE2, which are disposed at the lower portion of the input sensing part ISP, may not be connected to each other.

The pen sensing lines PSL1, PSL2, and PSL3-1 to PSL3-3 may include a plurality of first pen sensing lines PSL1, a plurality of second pen sensing lines PSL2, and a plurality of third-first, third-second, and third-third pen sensing lines PSL3-1, PSL3-2, and PSL3-3. The first pen sensing lines PSL1 and the third-first, third-second, and third-third pen sensing lines PSL3-1, PSL3-2, and PSL3-3 may be connected to the first pen sensing electrodes P-SE1. The second pen sensing lines PSL2 may be connected to the second pen sensing electrodes P-SE2.

The pair of the first pen sensing electrodes P-SE1 whose lower end portions are connected to each other may be connected to a corresponding first pen sensing line PSL1 among the first pen sensing lines PSL1. The upper end portions of the first pen sensing electrodes P-SE1 may be connected to the third-first pen sensing line PSL3-1 extending in the second direction DR2.

The third-second pen sensing line PSL3-2 and the third-third pen sensing line PSL3-3 may respectively extend from opposite end portions of the third-first pen sensing line PSL3-1 in the first direction DR1. The third-second pen sensing line PSL3-2 may be disposed at the left side portion of the input sensing part ISP and may be connected to a corresponding first pad PD1. The third-third pen sensing line PSL3-3 may be disposed at the right side portion of the input sensing part ISP and may be connected to a corresponding second pad PD2.

The left end portions of the second pen sensing electrodes P-SE2, which are disposed at the upper portion of the input sensing part ISP, may be connected to a corresponding second pen sensing line PSL2 among the second pen sensing lines PSL2. The second pen sensing line PSL2 connected to the second pen sensing electrodes P-SE2 disposed at the upper portion of the input sensing part ISP may be connected to a corresponding first pad PD1.

The right end portions of the second pen sensing electrodes P-SE2, which are disposed at the lower portion of the input sensing part ISP, may be connected to a corresponding second pen sensing line PSL2 among the second pen sensing lines PSL2. The second pen sensing line PSL2 connected to the second pen sensing electrodes P-SE2 disposed at the lower portion of the input sensing part ISP may be connected to a corresponding second pad PD2.

Although a timing diagram is not illustrated, the input sensing part ISP may be driven in a time-division manner to operate in a first sensing period and a second sensing period. The first sensing period and the second sensing period may be repeated. During the first sensing period, the first and second sensing electrodes SE1 and SE2 may be driven to sense the first input by the user’s touch. During the second sensing period, the second input by a touch of the pen may be sensed by the first and second pen sensing electrodes P-SE1 and P-SE2. An operation that senses the touch of the pen will be described in detail later.

Since the touch by the user and the touch by the pen are performed in the same input sensing part ISP, two input devices, such as a touch panel and a digitizer, do not need to be used, and thus a thickness of the display device DD may be reduced.

As an example, six first pen sensing electrodes P-SE1 and six second pen sensing electrodes P-SE2 are shown, however, the input sensing part ISP may include less than or more than six first pen sensing electrodes P-SE1 and include less than or more than six second pen sensing electrodes P-SE2.

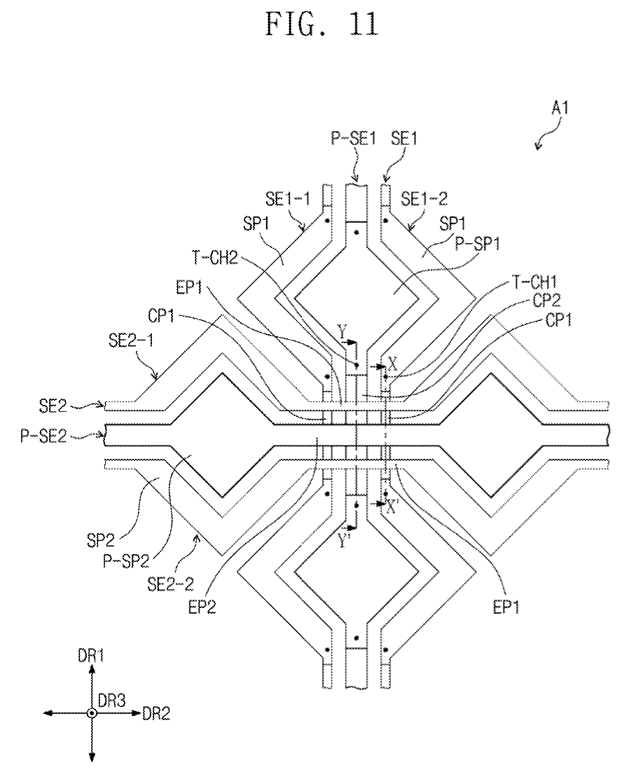

FIG. 11 is an enlarged view of a first area A1 shown in FIG. 10.

Referring to FIGS. 10 and 11, each of the first-first and first-second sensing electrodes SE1-1 and SE1-2 may include a plurality of first sensing portions SP1 arranged in the first direction DR1 and a plurality of first connection patterns CP1 connecting the first sensing portions SP1.

The first sensing portions SP1 may have a curved (or bent) shape. As an example, the first sensing portions SP1 of the first-first sensing electrode SE1-1 and the first sensing portions SP1 of the first-second sensing electrode SE1-2 may have a shape curved outward.

The first connection patterns CP1 may extend in the first direction DR1. Each of the first connection patterns CP1 may be disposed between two first sensing portions SP1 adjacent to each other and may connect the two first sensing portions SP1. An insulating layer may be disposed between the first connection patterns CP1 and the first sensing portions SP1, and the first connection patterns CP1 may be connected to the first sensing portions SP1 via first contact holes T-CH1 defined in the insulating layer.

Each of the second-first and second-second sensing electrodes SE2-1 and SE2-2 may include a plurality of second sensing portions SP2 arranged in the second direction DR2 and a plurality of first extension patterns EP1 extending from the second sensing portions SP2 in the second direction DR2. When viewed in the plane, the first extension patterns EP1 may extend to cross the first connection patterns CP1.

The second sensing portions SP2 may have a curved (or bent) shape. As an example, the second sensing portions SP2 of the second-first sensing electrode SE2-1 and the second sensing portions SP2 of the second-second sensing electrode SE2-2 may have a shape curved outward.

In each of the second-first and second-second sensing electrodes SE2-1 and SE2-2, the first extension patterns EP1 may be formed integrally with the second sensing portions SP2. Each of the first extension patterns EP1 may be disposed between two second sensing portions SP2 adjacent to each other in the second direction DR2 and may extend from two second sensing portions SP2.

The first sensing portions SP1 and the second sensing portions SP2 may not overlap each other, may be spaced apart from each other, and may be alternately arranged with each other. The first sensing portions SP1 may form a capacitance with the second sensing portions SP2.

The first and second sensing portions SP1 and SP2 and the first extension patterns EP1 may be disposed on the same layer. The first connection patterns CP1 may be disposed at a different layer from the first and second sensing portions SP1 and SP2 and the first extension patterns EP1. As an example, the first connection patterns CP1 may be disposed lower than the first and second sensing portions SP1 and SP2 and the first extension patterns EP1.

Each of the first pen sensing electrodes P-SE1 may include a plurality of first pen sensing portions P-SP1 arranged in the first direction DR1 and a plurality of second connection patterns CP2 connecting the first pen sensing portions P-SP1. The first pen sensing portions P-SP1 may have a lozenge shape, however, the shape of the first pen sensing portions P-SP1 is not limited thereto or thereby.

The second connection patterns CP2 may extend in the first direction DR1. Each of the second connection patterns CP2 may be disposed between two first pen sensing portions P-SP1 adjacent to each other in the first direction DR1 and may connect the two first pen sensing portions P-SP1. An insulating layer may be disposed between the second connection patterns CP2 and the first pen sensing portions P-SP1, and the second connection patterns CP2 may be connected to the first pen sensing portions P-SP1 via second contact holes T-CH2 defined in the insulating layer.

Each of the second pen sensing electrodes P-SE2 may include a plurality of second pen sensing portions P-SP2 arranged in the second direction DR2 and a plurality of second extension patterns EP2 extending from the second pen sensing portions P-SP2 in the second direction DR2. When viewed in the plane, the first and second extension patterns EP1 and EP2 may extend to cross the first and second connection patterns CP1 and CP2.

The second pen sensing portions P-SP2 may have a lozenge shape, however, the shape of the second pen sensing portions P-SP2 is not limited thereto or thereby. The second extension patterns EP2 may be formed integrally with the second pen sensing portions P-SP2. Each of the second extension patterns EP2 may be disposed between two second pen sensing portions P-SP2 adjacent to each other in the second direction DR2 and may extend from the two second pen sensing portions P-SP2.

The first pen sensing portions P-SP1, the second pen sensing portions P-SP2, and the second extension patterns EP2 may be disposed on the same layer as the first and second sensing portions SP1 and SP2 and the first extension patterns EP1. The second connection patterns CP2 and the first connection patterns CP1 may be disposed on the same layer.

In FIG. 10, the first sensing lines TL may extend to cross the first pen sensing lines PSL1 while being insulated from the first pen sensing lines PSL1. As an example, referring to FIGS. 10 and 11, the first sensing lines TL may be formed integrally with the first sensing portions SP1 adjacent to the lower side portion of the active area AA and may extend from the first sensing portions SP1. The first pen sensing lines PSL1 may be formed integrally with the second connection patterns CP2 adjacent to the lower side portion of the active area AA and may extend from the second connection patterns CP2.

In FIG. 10, the first pen sensing lines PSL1 may be disposed lower than the first sensing lines TL. An insulating layer may be disposed between the first pen sensing lines PSL1 and the first sensing lines TL.

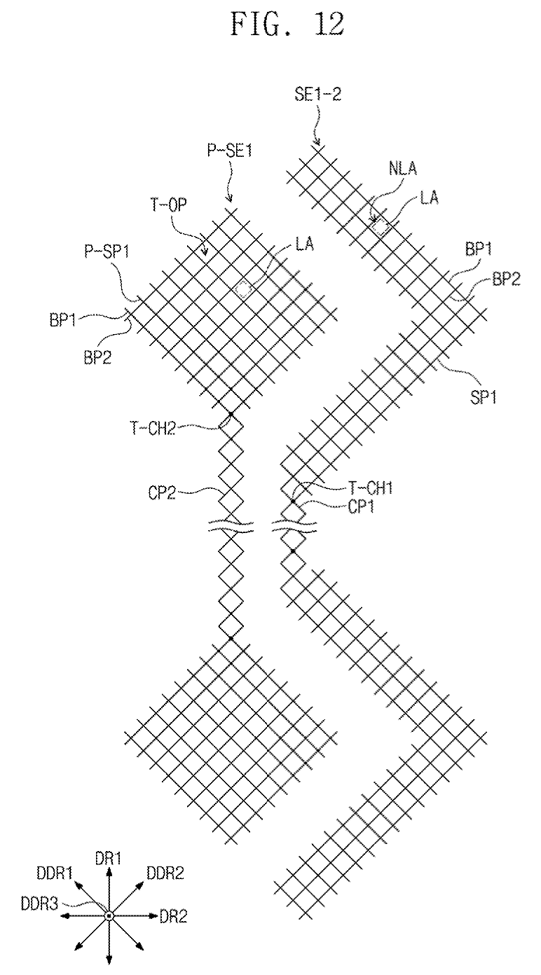

FIG. 12 is a view of a configuration of the first pen sensing electrode and the first-second pen sensing electrode shown in FIG. 11.

Referring to FIG. 12, the first pen sensing electrode P-SE1 and the first-second sensing electrode SE1-2 may have a mesh shape. As an example, each of the first pen sensing electrode P-SE1 and the first-second sensing electrode SE1-2 may include a plurality of first branches BP1 extending in a first diagonal direction DDR1 and a plurality of second branches BP2 extending in a second diagonal direction DDR2.

The first diagonal direction DDR1 may cross the first and second directions DR1 and DR2 on a plane defined by the first and second directions DR1 and DR2. The second diagonal direction DDR2 may cross the first diagonal direction DDR1 on the plane defined by the first and second directions DR1 and DR2.

The first and second branches BP1 and BP2 may cross each other and may be formed integrally with each other. The mesh shape of the first pen sensing electrode P-SE1 and the first-second sensing electrode SE1-2 may be defined by the first and second branches BP1 and BP2.

Although not shown in FIG. 12, the first-first sensing electrode SE1-1, the second pen sensing electrode P-SE2, and the second-first and second-second sensing electrodes SE2-1 and SE2-2 shown in FIG. 11 may have the same mesh shape as those of components shown in FIG. 12.

Openings T-OP having a lozenge shape may be defined by the first and second branches BP1 and BP2. The light emitting areas LA of the pixels PX may be defined in the openings T-OP, respectively. Accordingly, the first and second branches BP1 and BP2 may overlap the non-light-emitting area NLA. That is, the first-second sensing electrode SE1-2 and the second pen sensing electrode P-SE2 may overlap the non-light-emitting area NLA.

Since the first and second branches BP1 and BP2 are arranged in the non-light-emitting area NLA, lights emitted from the light emitting elements OLED of the pixels PX may be emitted normally without being affected by the first-second sensing electrode SE1-2 and the second pen sensing electrode P-SE2.

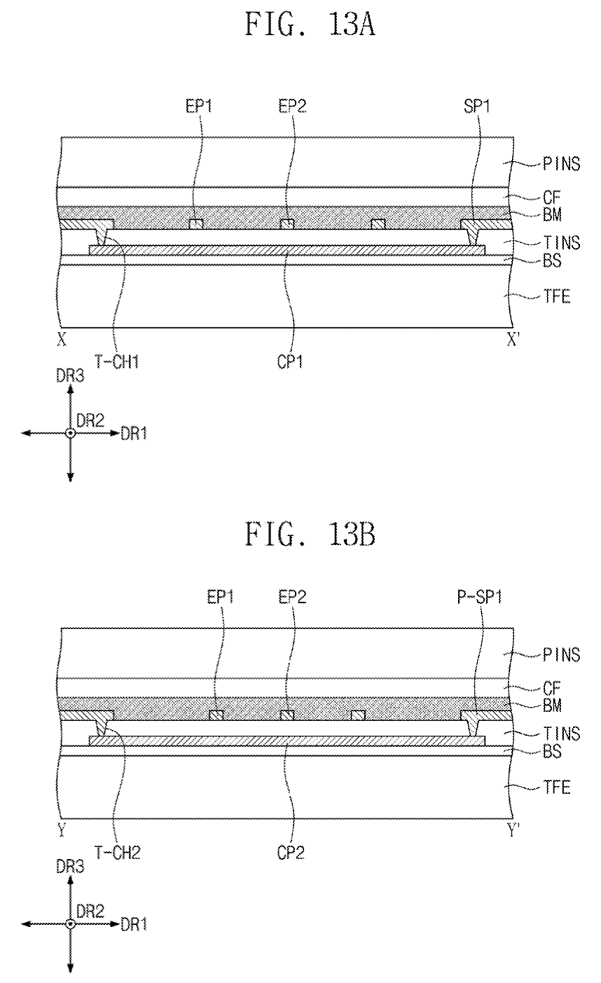

FIG. 13A is a cross-sectional view taken along a line X-X’ of FIG. 11. FIG. 13B is a cross-sectional view taken along a line Y-Y’ of FIG. 11.

Referring to FIGS. 13A and 13B, the base layer BS may be disposed on the thin film encapsulation layer TFE, and the first connection pattern CP1 and the second connection pattern CP2 may be disposed on the base layer BS. The first connection pattern CP1 and the second connection pattern CP2 may be formed by the first conductive pattern CTL1.

The insulating layer TINS may be disposed on the base layer BS to cover the first and second connection patterns CP1 and CP2. The first sensing portions SP1, the first pen sensing portions P-SP1, and the first and second extension patterns EP1 and EP2 may be disposed on the insulating layer TINS. Although not shown in figures, the second sensing portions SP2 formed integrally with the first extension patterns EP1 and the second pen sensing portions P-SP2 formed integrally with the second extension patterns EP2 may be disposed on the insulating layer TINS.

The first sensing portions SP1 may be connected to the first connection pattern CP1 via the first contact holes T-CH1 defined in the insulating layer TINS. The first pen sensing portions P-SP1 may be connected to the second connection pattern CP2 via the second contact holes T-CH2 defined in the insulating layer TINS.

The black matrix BM may be disposed on the insulating layer TINS to cover the first sensing portions SP1, the first pen sensing portions P-SP1, and the first and second extension patterns EP1 and EP2. The color filter CF may be disposed on the black matrix BM, and the planarization insulating layer PINS may be disposed on the color filter CF.

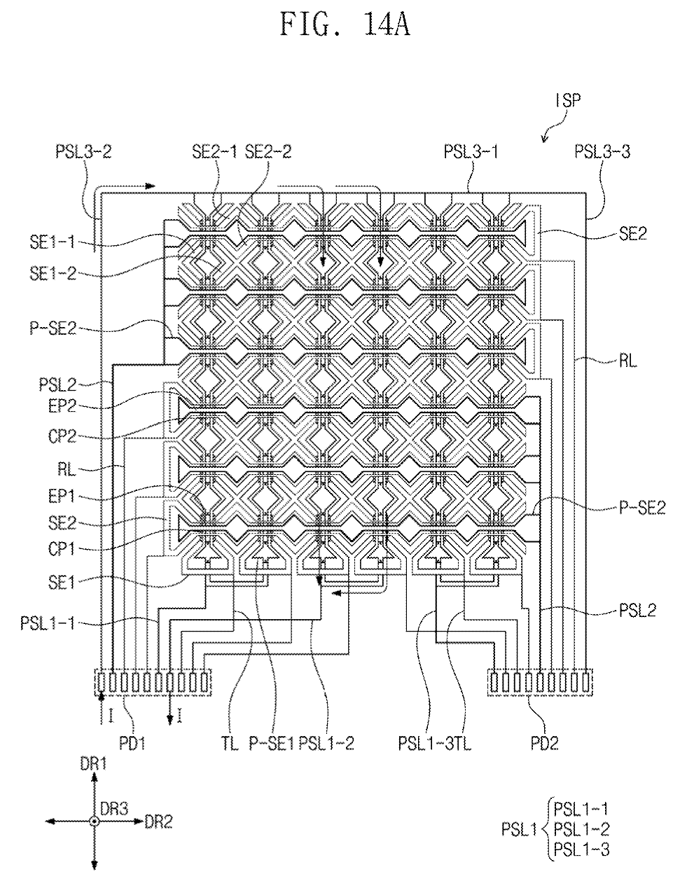

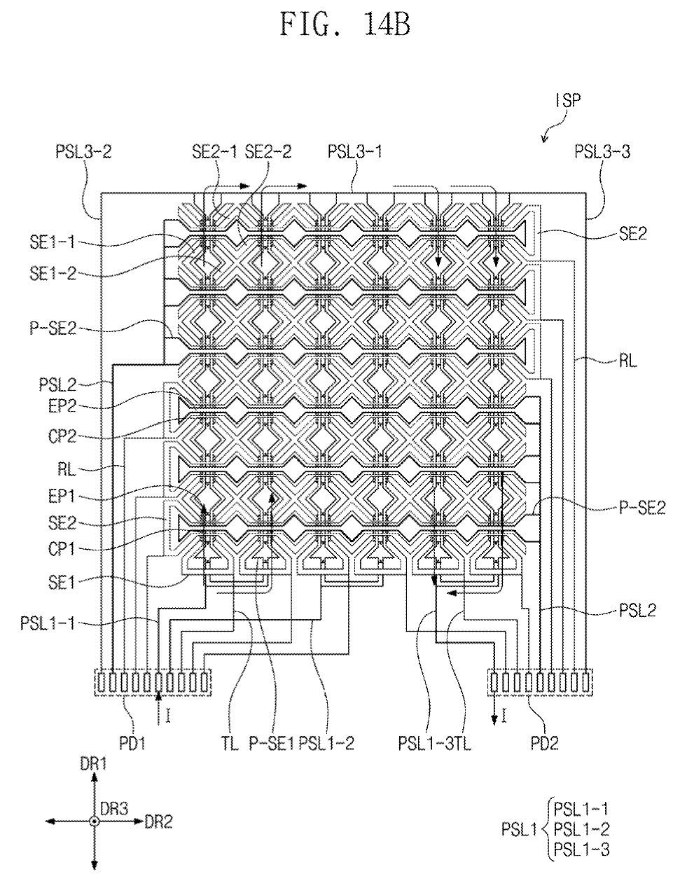

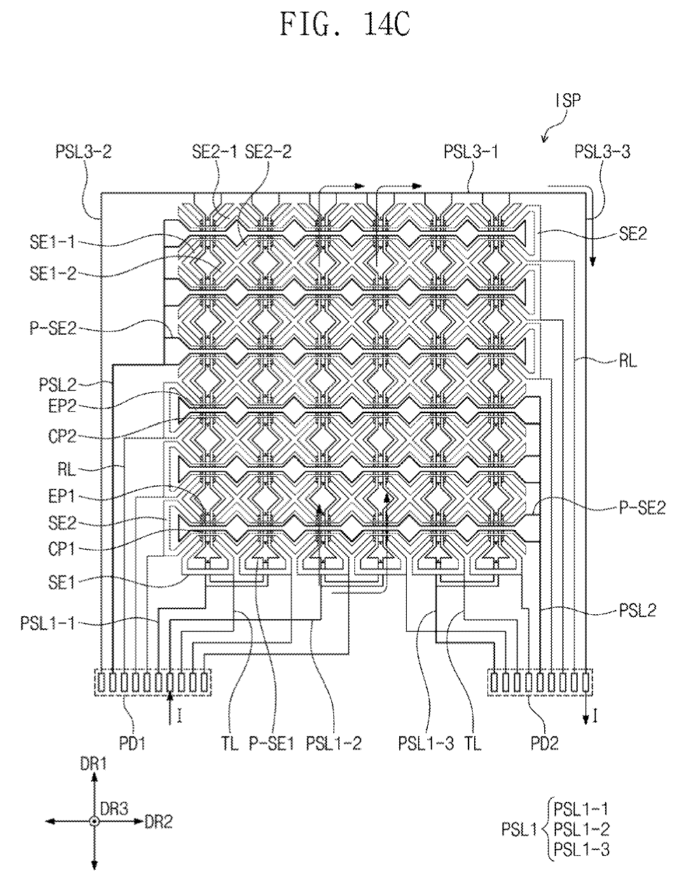

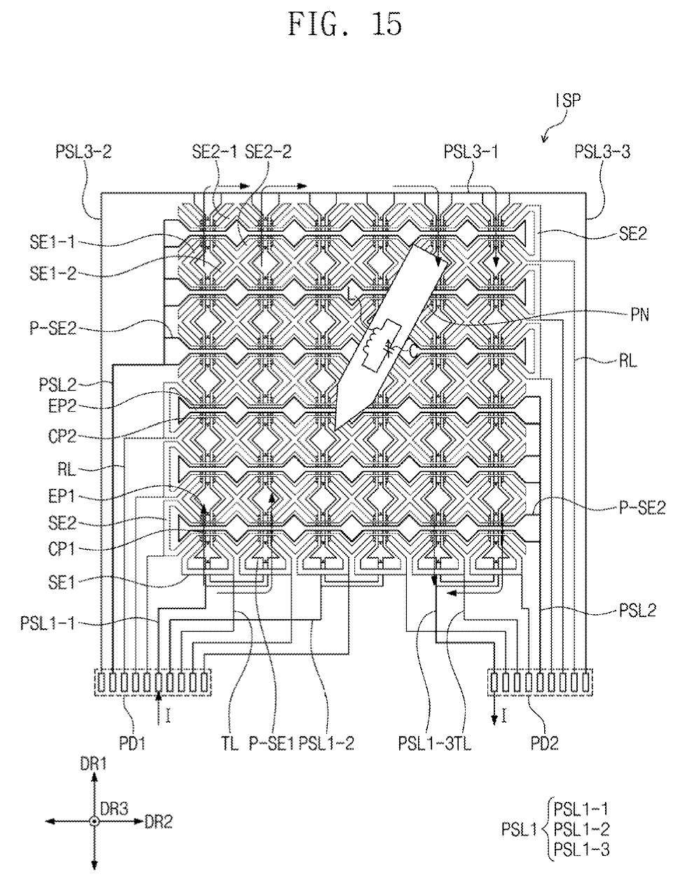

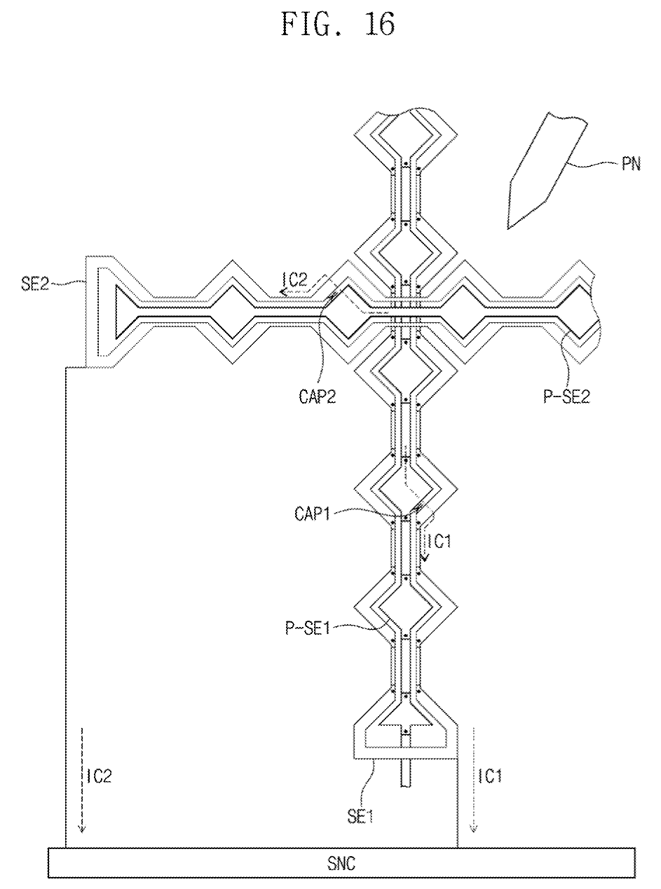

FIGS. 14A-14C are views illustrating an operation of the pen sensing electrodes shown in FIG. 10. FIG. 15 is a view illustrating a charging operation of the pen located above an input sensing part. FIG. 16 is a view illustrating a sensing operation for a touch by the pen shown in FIG. 15.

In FIGS. 14A-14C and 15, for brevity of description, a boundary between the active area AA and the non-active area NAA of the input sensing part ISP is omitted. Hereinafter, the first pen sensing lines PSL1 are referred to as first-first, first-second, and first-third pen sensing lines PSL1-1, PSL1-2, and PSL1-3 in order from left to right in FIGS. 14A-14C and 15.

Referring to FIG. 14A, although a timing diagram is not shown, the second sensing period described above may include a charging period and a pen sensing period following the charging period. During the charging period, the first-first, first-second, and first-third pen sensing lines PSL1-1, PSL1-2, and PSL1-3, the first pen sensing electrodes P-SE1, and the third-first, third-second, and third-third pen sensing lines PSL3-1, PSL3-2, and PSL3-3 may be driven to sequentially form a coil().

The first and second pads PD1 and PD2 may be connected to a driving circuit (not shown) of the sensing IC. The driving circuit may apply a driving signal to the first-first, first-second, and first-third pen sensing lines PSL1-1, PSLb-2, and PSL1-3, the first pen sensing electrodes P-SE1, and the third-first, third-second, and third-third pen sensing lines PSL3-1, PSL3-2, and PSL3-3 in a certain order.

In a first period of the charging period, the driving circuit may be connected to the first pad PD1 connected to the third-second pen sensing line PSL3-2 and the first pad PD1 connected to the first-second pen sensing line PSL1-2. The driving circuit may apply a driving current I to the third-second pen sensing line PSL3-2. The driving current I may flow through the third-second pen sensing line PSL3-2, the first pen sensing electrodes P-SE1 connected to the first-second pen sensing line PSL1-2, and the first-second pen sensing line PSL1-2.

Accordingly, the third-second pen sensing line PSL3-2, the first pen sensing electrodes P-SE1 connected to the first-second pen sensing line PSL1-2, and the first-second pen sensing line PSL1-2 may form a coil, and the driving current I may flow through the third-second pen sensing line PSL3-2, the first pen sensing electrodes P-SE1 connected to the first-second pen sensing line PSL1-2, and the first-second pen sensing line PSL1-2.

Referring to FIG. 14B, in a second period following the first period of the charging period, the driving circuit may be connected to the first pad PD1 connected to the first-first pen sensing line PSL1-1 and the second pad PD2 connected to the first-third pen sensing line PSL1-3. The driving circuit may apply the driving current I to the first-first pen sensing line PSL1-1. The driving current I may flow through the first-first pen sensing line PSL1-1, the first pen sensing electrodes P-SE1 connected to the first-first pen sensing line PSL1-1, the first pen sensing electrodes P-SE1 connected to the first-third pen sensing line PSL1-3, and the first-third pen sensing line PSL1-3.

Accordingly, the first-first pen sensing line PSL1-1, the first pen sensing electrodes P-SE1 connected to the first-first pen sensing line PSL1-1, the first pen sensing electrodes P-SE1 connected to the first-third pen sensing line PSL1-3, and the first-third pen sensing line PSL1-3 may form a coil, and the driving current I may flow through the first-first pen sensing line PSL1-1, the first pen sensing electrodes P-SE1 connected to the first-first pen sensing line PSL1-1, the first pen sensing electrodes P-SE1 connected to the first-third pen sensing line PSL1-3, and the first-third pen sensing line PSL1-3.

Referring to FIG. 14C, the driving circuit may be connected to the first pad PD1 connected to the first-second pen sensing line PSL1-2 and the second pad PD2 connected to the third-third pen sensing line PSL3-3 in a third period following the second period of the charging period. The driving circuit may apply the driving current I to the first-second pen sensing line PSL1-2. The driving current I may flow through the first-second pen sensing line PSL1-2, the first pen sensing electrodes P-SE1 connected to the first-second pen sensing line PSL1-2, and the third-third pen sensing line PSL3-3.

Accordingly, the first-second pen sensing line PSL1-2, the first pen sensing electrodes P-SE1 connected to the first-second pen sensing line PSL1-2, and the third-third pen sensing line PSL3-3 may form a coil, and the driving current I may flow through the first-second pen sensing line PSL1-2, the first pen sensing electrodes P-SE1 connected to the first-second pen sensing line PSL1-2, and the third-third pen sensing line PSL3-3.

Referring to FIG. 15, as described with reference to FIGS. 14A-14C, the driving current I may flow through the first-first, first-second, and first-third pen sensing lines PSL1-1, PSL1-2, and PSL1-3, the first pen sensing electrodes P-SE1, and the third-first, third-second, and third-third pen sensing lines PSL3-1, PSL3-2, and PSL3-3, and a pen PN may be placed above the input sensing part ISP.

The pen PN may include an inductor L and a capacitor C connected to the inductor L. The capacitor C may be a variable capacitor whose capacity is variable. The inductor L and the capacitor C may form an LC resonant circuit. When the pen PN is placed on the display module DM, the capacitor C may be charged for the charging period.

As an example, the pen PN may be disposed between the first pen sensing electrodes P-SE1 connected to the first-first pen sensing line PSL1-1 and the first pen sensing electrodes P-SE1 connected to the first-third pen sensing line PSL1-3.

In this case, a magnetic flux may be generated by the driving current I flowing through the first-first pen sensing line PSL1-1, the first pen sensing electrodes P-SE1 connected to the first-first pen sensing line PSL1-1, the first pen sensing electrodes P-SE1 connected to the first-third pen sensing line PSL1-3, and the first-third pen sensing line PSL1-3. The magnetic flux may be introduced to a ferrite core surrounding a coil of the inductor L, and in this case, an induced current may be generated in the coil of the inductor L. The capacitor C may be charged with electric charges by the induced current.

During the charging period, a constant voltage may be applied to the second pen sensing electrodes P-SE2 through the second pen sensing lines PSL2.

Hereinafter, for the convenience of explanation, FIG. 16 shows one first pen sensing electrode P-SE1 and one second pen sensing electrode P-SE2 through which the induced current generated by the pen PN flows. In addition, the first sensing electrode SE1 adjacent to the first pen sensing electrode P-SE1 and the second sensing electrode SE2 adjacent to the second pen sensing electrode P-SE2 are shown together with the first pen sensing electrode P-SE1 and the second pen sensing electrode P-SE2.

Referring to FIG. 15, during the pen sensing period following the charging period, a sensing circuit SNC of the sensing IC may be connected to the first and second sensing electrodes SE1 and SE2. During the pen sensing period, the driving current I may not be applied to the first-first, first-second, and first-third pen sensing lines PSL1-1, PSL1-2, and PSL1-3, the first pen sensing electrodes P-SE1, and the third-first, third-second, and third-third pen sensing lines PSL3-1, PSL3-2, and PSL3-3.

The LC resonant circuit of the pen PN may generate the magnetic flux while consuming the charged electric charges. The induced current may be generated in the first pen sensing electrode P-SE1 and the second pen sensing electrode P-SE2 by the magnetic flux.

A first induced current IC1 generated in the first pen sensing electrode P-SE1 may be provided to the first sensing electrode SE1 by a first capacitor CAP1 formed by the first sensing electrode SE1 and the first pen sensing electrode P-SE1 and then may be provided to the sensing circuit SNC. A second induced current IC2 generated in the second pen sensing electrode P-SE2 may be provided to the second sensing electrode SE2 by a second capacitor CAP2 formed by the second sensing electrode SE2 and the second pen sensing electrode P-SE2 and then may be provided to the sensing circuit SNC.

The sensing circuit SNC may sense the first induced current IC1 and the second induced current IC2 provided via the first and second sensing electrodes SE1 and SE2, and thus may sense a location of the pen PN. That is, a touch generated by the pen PN may be sensed by the first and second pen sensing electrodes P-SE1 and P-SE2 and the first and second sensing electrodes SE1 and SE2.

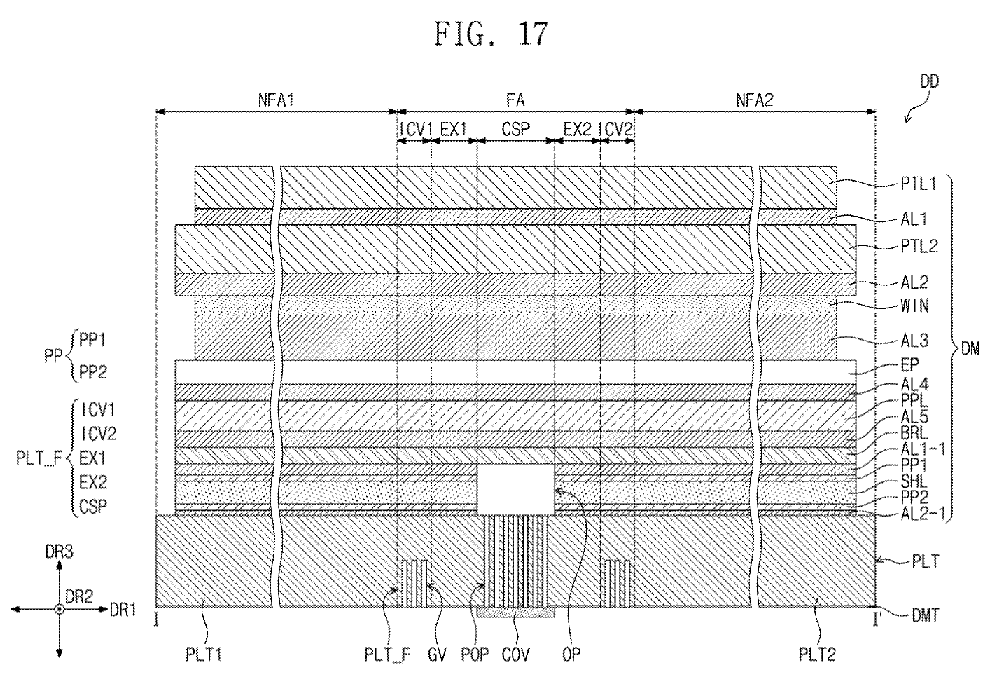

FIG. 17 is a cross-sectional view of the display device taken along a line I-I’ of FIG. 8.

As an example, the electronic panel EP including the display panel DP and the components disposed above and below the electronic panel EP are shown in FIG. 17.

Referring to FIG. 17, the display device DD may include the display module DM, a support plate PLT, a cover layer COV, and a dummy metal layer DMT. The support plate PLT may be disposed under the display module DM to support the display module DM. The cover layer COV and the dummy metal layer DMT may be disposed under the support plate PLT.

The display module DM may be a flexible display module. The display module DM may include the first non-folding area NFA1, the folding area FA, and the second non-folding area NFA2. As the folding area FA is folded with respect to the folding axis FX, the display module DM may be folded.

The display module DM may include the electronic panel EP, the window WIN, a first protective layer PTL1, a second protective layer PTL2, a panel protective layer PPL, a barrier layer BRL, an electromagnetic shielding layer SHL, a planarization layer PP, first, second, third, fourth, and fifth adhesive layers AL1 to AL5 and first and second adhesive layers AL1-1 and AL2-1. The window WIN, the first protective layer PTL1, and the second protective layer PTL2 may be disposed on or above the electronic panel EP, and the panel protective layer PPL, the barrier layer BRL, the electromagnetic shielding layer SHL, and the planarization layer PP may be disposed on or under the electronic panel EP.

The window WIN may be disposed on the electronic panel EP. The window WIN may protect the electronic panel EP from an external scratche. The window WIN may have an optically transparent property. The window WIN may include a glass material, however, the present disclosure is not limited thereto or thereby. According to an embodiment, the window WIN may include a synthetic resin film.

The window WIN may have a single-layer or multi-layer structure. As an example, the window WIN may include a plurality of synthetic resin films attached to each other by an adhesive or a glass substrate and a synthetic resin film attached to the glass substrate by an adhesive.

The second protective layer PTL2 may be disposed on the window WIN, and the first protective layer PTL1 may be disposed on the second protective layer PTL2. Accordingly, the second protective layer PTL2 may be disposed between the first protective layer PTL1 and the window WIN. The first protective layer PTL1 and the second protective layer PTL2 may protect the window WIN and the electronic panel EP. In addition, the first protective layer PTL1 and the second protective layer PTL2 may enhance an impact resistance of the display device DD against an external impact.

The first protective layer PTL1 may include a flexible film including a plastic material, such as polyethylene terephthalate, and a hard coating layer coated on an upper surface of the flexible film. The flexible film of the first protective layer PTL1 may include any one or more of various plastic materials in addition to polyethylene terephthalate.

The second protective layer PTL2 may include a flexible film including a plastic material, such as polyethylene terephthalate, a hard coating layer coated on an upper surface of the flexible film, and a dummy film disposed to be in contact with a lower surface of the flexible film. The flexible film of the second protective layer PTL2 may include any one or more of various plastic materials in addition to polyethylene terephthalate. The dummy film of the second protective layer PTL2 may include thermoplastic polyurethane or rubber, but the present disclosure is not limited thereto and the dummy film may include any one or more of various elastic materials.

The panel protective layer PPL may be disposed under the electronic panel EP. The panel protective layer PPL may be disposed under the display panel DP shown in FIG. 6 and may protect a lower portion of the display panel DP. The panel protective layer PPL may include a flexible plastic material, such as polyethylene terephthalate (PET), however, the present disclosure is not limited thereto or thereby. According to an embodiment, the panel protective layer PPL may include any one or more of various plastic materials.

The barrier layer BRL may be disposed under the display panel DP of the electronic panel EP. In detail, the barrier layer BRL may be disposed under the panel protective layer PPL. The barrier layer BRL may increase a resistance to a compressive force caused by an external pressure. Accordingly, the barrier layer BRL may prevent the display panel DP from being deformed. The barrier layer BRL may include a flexible plastic material, such as polyimide or polyethylene terephthalate.

The barrier layer BRL may have a color that absorbs a light. As an example, the barrier layer BRL may have a black color. In this case, when the display module DM is viewed from above, components disposed under the barrier layer BRL may not be visible to the user.

The electromagnetic shielding layer SHL may be disposed under the barrier layer BRL. The electromagnetic shielding layer SHL may shield an electromagnetic wave applied to the input sensing part ISP from below the display device DD. When an electromagnetic signal is applied to the input sensing part ISP, a sensing sensitivity of the input sensing part ISP may be reduced. Since the electromagnetic wave applied to the input sensing part ISP are shielded, the sensing sensitivity of the input sensing part ISP may be enhanced.

The electromagnetic shielding layer SHL may include a magnetic metal powder to shield against the electromagnetic wave. In detail, the electromagnetic shielding layer SHL may include a resin and the magnetic metal powder dispersed in the resin. The electromagnetic shielding layer SHL may be manufactured in a form of a film and disposed under the barrier layer BRL. The electromagnetic shielding layer SHL may have a modulus of about 2.8 GPa.

The planarization layer PP may include a first planarization layer PP1 disposed on the electromagnetic shielding layer SHL and a second planarization layer PP2 disposed under the electromagnetic shielding layer SHL. The first planarization layer PP1 may be disposed between the display panel DP of the electronic panel EP and the electromagnetic shielding layer SHL. In detail, the first planarization layer PP1 may be disposed between the barrier layer BRL and the electromagnetic shielding layer SHL. The support plate PLT may be disposed under the electromagnetic shielding layer SHL, and the second planarization layer PP2 may be disposed between the electromagnetic shielding layer SHL and the support plate PLT.

The first planarization layer PP1 may have a modulus smaller than the modulus of the electromagnetic shielding layer SHL. For example, the first planarization layer PP1 may have a modulus in the range of about 0.6 GPa to about 1.8 GPa at room temperature, for example, at about 30° C, and specifically, may have a modulus of about 1.3 GPa.

The first planarization layer PP1 may have a thickness smaller than a thickness of the electromagnetic shielding layer SHL. For example, the first planarization layer PP1 may have a thickness in a range of about 1 micrometer (μm) to about 10 micrometers (μm) in the third direction DR3, and specifically, may have a thickness of about 10 micrometers (μm). For example, the electromagnetic shielding layer SHL may have a thickness in a range of about 20 micrometers (μm) to about 50 micrometers (μm), and specifically, may have a thickness of about 34 micrometers (μm) in the third direction DR3.

The first planarization layer PP1 may be coated on an upper surface of the electromagnetic shielding layer SHL. Accordingly, the first planarization layer PP1 may be in direct contact with the upper surface of the electromagnetic shielding layer SHL. The first planarization layer PP1 may include a resin. For example, the first planarization layer PP1 may include a urethane acrylate-based resin. After the resin is directly coated on the upper surface of the electromagnetic shielding layer SHL and cured, the first planarization layer PP1 may be formed.

The second planarization layer PP2 may include the same material, the same modulus, and the same thickness as those of the first planarization layer PP1. Accordingly, the second planarization layer PP2 may have a smaller modulus and a smaller thickness than those of the electromagnetic shielding layer SHL. The second planarization layer PP2 may be coated on a lower surface of the electromagnetic shielding layer SHL and may be in direct contact with the lower surface of the electromagnetic shielding layer SHL. The second planarization layer PP2 may be formed by directly coating a resin on the lower surface of the electromagnetic shielding layer SHL and then curing the coated resin.

The electromagnetic shielding layer SHL may have a rough surface due to a particle of the magnetic metal powder. A surface quality of the display module DM may be degraded due to the rough surface of the electromagnetic shielding layer SHL.

In an embodiment of the present disclosure, the first planarization layer PP1 and the second planarization layer PP2 may be formed by providing a flowable resin respectively on the upper and lower surfaces of the electromagnetic shielding layer SHL and curing the resin. Accordingly, the first planarization layer PP1 and the second planarization layer PP2, each having a modulus lower than that of the electromagnetic shielding layer SHL, may be coated on the upper and lower surfaces of the electromagnetic shielding layer SHL, respectively.

The flowable resin may be provided on the upper and lower surfaces of the electromagnetic shielding layer SHL to spread more evenly. According to this structure, the first and second planarization layers PP1 and PP2, which have a high degree of flatness, may be disposed on the upper and lower surfaces of the electromagnetic shielding layer SHL, respectively. The first planarization layer PP1 may provide a flat surface on the electromagnetic shielding layer SHL, and the second planarization layer PP2 may provide a flat surface under the electromagnetic shielding layer SHL. As a result, the surface quality of the display module DM may be improved.

The first adhesive layer AL1 may be disposed between the first protective layer PTL1 and the second protective layer PTL2. The first protective layer PTL1 and the second protective layer PTL2 may be coupled to each other by the first adhesive layer AL1.

The second adhesive layer AL2 may be disposed between the second protective layer PTL2 and the window WIN. The second protective layer PTL2 and the window WIN may be coupled to each other by the second adhesive layer AL2.

The third adhesive layer AL3 may be disposed between the window WIN and the electronic panel EP. The window WIN and the electronic panel EP may be coupled to each other by the third adhesive layer AL3.

The fourth adhesive layer AL4 may be disposed between the electronic panel EP and the panel protective layer PPL. The electronic panel EP and the panel protective layer PPL may be coupled to each other by the fourth adhesive layer AL4.

The fifth adhesive layer AL5 may be disposed between the panel protective layer PPL and the barrier layer BRL. The panel protective layer PPL and the barrier layer BRL may be coupled to each other by the fifth adhesive layer AL5.

The first adhesive layer AL1-1 may be disposed between the barrier layer BRL and the electromagnetic shielding layer SHL, and the first planarization layer PP1 may be disposed between the first adhesive layer AL1-1 and the electromagnetic shielding layer SHL. The barrier layer BRL and the first planarization layer PP1 may be coupled to each other by the first adhesive layer AL1-1.

The second adhesive layer AL2-1 may be disposed between the support plate PLT and the electromagnetic shielding layer SHL, and the second planarization layer PP2 may be disposed between the second adhesive layer AL2-1 and the electromagnetic shielding layer SHL. The support plate PLT and the second planarization layer PP2 may be coupled to each other by the second adhesive layer AL2-1.

The first to fifth adhesive layers AL1 to AL5 and the first and second adhesive layers AL1-1 and AL2-1 may include a transparent adhesive such as a pressure sensitive adhesive or an optical transparent adhesive, however, the type of adhesive is not limited thereto or thereby.

An opening OP may be defined in the electromagnetic shielding layer SHL, the first and second planarization layers PP1 and PP2, and the first and second adhesive layers AL1-1 and AL2-1 to overlap the folding area FA. Flexibility of the folding area FA of the display module DM may be enhanced by the opening OP, and the folding area FA of the display module DM may be easily bent. Due to the opening OP, each of the electromagnetic shielding layer SHL, the first and second planarization layers PP1 and PP2, and the first and second adhesive layers AL1-1 and AL2-1 may be separated into left and right portions in the folding area FA.

The first protective layer PTL1 and the first adhesive layer AL1 may have the same width, and an edge of the first protective layer PTLb may overlap with an edge of the first adhesive layer AL1. The first protective layer PTL1 may have a thickness greater than that of the first adhesive layer AL1 in the third direction DR3. For example, the first protective layer PTL1 may have a thickness of about 70 micrometers (μm), and the first adhesive layer AL1 may have a thickness of about 25 micrometers (μm) in the third direction DR3.

The second protective layer PTL2 and the second adhesive layer AL2 may have the same width, and an edge of the second protective layer PTL2 may overlap with an edge of the second adhesive layer AL2. The second protective layer PTL2 and the second adhesive layer AL2 may have a width greater than those of the first protective layer PTL1 and the first adhesive layer AL1. The edges of the second protective layer PTL2 and the second adhesive layer AL2 may be disposed outwardly of the edges of the first protective layer PTL1 and the first adhesive layer AL1.

The second protective layer PTL2 may have a thickness greater than that of the second adhesive layer AL2 in the third direction DR3. As an example, the second protective layer PTL2 may have a thickness of about 79 micrometers (μm), and the second adhesive layer AL2 may have a thickness of about 35 micrometers (μm) in the third direction DR3.

The window WIN and the third adhesive layer AL3 may have the same width, and an edge of the window WIN may overlap with an edge of the third adhesive layer AL3. The window WIN and the third adhesive layer AL3 may have a width smaller than those of the second protective layer PTL2 and the second adhesive layer AL2. The edges of the window WIN and the third adhesive layer AL3 may be disposed inwardly of the edges of the second protective layer PTL2 and the second adhesive layer AL2.

The window WIN may have a thickness smaller than that of the third adhesive layer AL3 in the third direction DR3. As an example, the window WIN may have a thickness of about 30 micrometers (μm), and the third adhesive layer AL3 may have a thickness of about 75 micrometers (μm) in the third direction DR3.

The electronic panel EP, the panel protective layer PPL, the barrier layer BRL, the electromagnetic shielding layer SHL, the first and second planarization layers PP1 and PP2, the fourth and fifth adhesive layers AL4 and AL5, and the first and second adhesive layers AL1-1 and AL2-1 may have the same width. Edges of the electronic panel EP, the panel protective layer PPL, the barrier layer BRL, the electromagnetic shielding layer SHL, the first and second planarization layers PP1 and PP2, the fourth and fifth adhesive layers AL4 and AL5, and the first and second adhesive layers AL1-1 and AL2-1 may overlap one another.

The edges of the electronic panel EP, the panel protective layer PPL, the barrier layer BRL, the electromagnetic shielding layer SHL, the first and second planarization layers PP1 and PP2, the fourth and fifth adhesive layers AL4 and AL5, and the first and second adhesive layers AL1-1 and AL2-1 may be disposed outwardly of the edges of the window WIN and the third adhesive layer AL3.

The electronic panel EP may have a thickness smaller than that of the panel protective layer PPL in the third direction DR3. As an example, the electronic panel EP may have a thickness of about 30micrometers (μm) in the third direction DR3. As an example, the panel protective layer PPL may have a thickness of about 50 micrometers (μm) in the third direction DR3.

The barrier layer BRL may have a thickness smaller than that of the panel protective layer PPL in the third direction DR3. As an example, the barrier layer BRL may have a thickness of about 25 micrometers (μm) in the third direction DR3.

As described above, the electromagnetic shielding layer SHL may have a thickness of about 34 micrometers (μm) in the third direction DR3, and each of the first and second planarization layers PP1 and PP2 may have a thickness of about 10 micrometers (μm) in the third direction DR3.

As an example, each of the fourth adhesive layer AL4 and the fifth adhesive layer AL5 may have a thickness of about 25 micrometers (μm) in the third direction DR3. As an example, the first adhesive layer AL1-1 may have a thickness of about 16 micrometers (μm) in the third direction DR3, and the second adhesive layer AL2-1 may have a thickness of about 8 micrometers (μm) in the third direction DR3.

A plurality of lattice openings POP may be defined in the support plate PLT. The lattice openings POP may be defined penetrating through a portion of the support plate PLT in the third direction DR3. When viewed in the plane, the lattice openings POP may overlap the folding area FA. Grooves GV may be defined in a lower surface of the support plate PLT. When viewed in the plane, the grooves GV may overlap the folding area FA.

The support plate PLT may include a metal material. For example, the support plate PLT may include a stainless steel. As an example, the support plate PLT may have a thickness in a range from about 80 micrometers (μm) to about 150 micrometers (μm) in the third direction DR3, and more specifically, may have a thickness of about 120 micrometers (μm).

The support plate PLT may include a first support plate PLT1, a second support plate PLT2, and a folding portion PLT_F. As an example, boundaries of the first support plate PLT1, the second support plate PLT2, and the folding portion PLT_F are illustrated by dotted lines on the support plate PLT.

The folding portion PLT_F may be disposed between the first support plate PLT1 and the second support plate PLT2. The first support plate PLT1, the folding portion PLT_F, and the second support plate PLT2 may be arranged in the first direction DR1. The lattice openings POP may be defined in the folding portion PLT_F. The grooves GV may be defined in a lower surface of the folding portion PLT_F.

The first support plate PLT1 may be disposed in the first non-folding area NFA1 and may overlap the first non-folding area NFA1 when viewed in the plane. The second support plate PLT2 may be disposed in the second non-folding area NFA2 and may overlap the second non-folding area NFA2 when viewed in the plane. The folding portion PLT_F may be disposed in the folding area FA and may overlap the folding area FA when viewed in the plane.

The folding portion PLT_F may include a curved portion CSP, a first extension portion EX1, a second extension portion EX2, a first reverse curvature portion ICV1, and a second reverse curvature portion ICV2. As an example, boundaries of the curved portion CSP, the first extension portion EX1, the second extension portion EX2, the first reverse curvature portion ICV1, and the second reverse curvature portion ICV2 are illustrated by dotted lines on the support plate PLT. For convenience of illustration, reference characters ICV1, EX1, CSP, EX2, and ICV2 are depicted on a top portion of the display module DM by extending corresponding boundary dotted lines upward.

The curved portion CSP, the first extension portion EX1, the second extension portion EX2, the first reverse curvature portion ICV1, and the second reverse curvature portion ICV2 may be arranged in the first direction DR1. As an example, the curved portion CSP may be disposed at a center of the folding portion PLT_F.

The curved portion CSP may be disposed between the first reverse curvature portion ICV1 and the second reverse curvature portion ICV2. The first extension portion EX1 may be disposed between the curved portion CSP and the first reverse curvature portion ICV1. The second extension portion EX2 may be disposed between the curved portion CSP and the second reverse curvature portion ICV2. The curved portion CSP may be disposed between the first extension portion EX1 and the second extension portion EX2.

The first reverse curvature portion ICV1 may be disposed between the first support plate PLT1 and the first extension portion EX1. The second reverse curvature portion ICV2 may be disposed between the second support plate PLT2 and the second extension portion EX2.

The lattice openings POP may be defined in the curved portion CSP. The grooves GV may be defined in a lower surface of each of the first and second reverse curvature portions ICV1 and ICV2. The opening OP may be defined to overlap the curved portion CSP. That is, the electromagnetic shielding layer SHL, the first and second planarization layers PP1 and PP2, and the first and second adhesive layers AL1-1 and AL2-1 may be opened in an area overlapping the curved portion CSP.

The dummy metal layer DMT may be disposed under the support plate PLT. The dummy metal layer DMT may be formed on the lower surface of the support plate PLT by plating or depositing. The dummy metal layer DMT may be in direct contact with the lower surface of the support plate PLT. The dummy metal layer DMT may include, for example but not limited to, a stainless steel, a titanium alloy, or copper. The support plate PLT and the dummy metal layer DMT may provide a heat dissipation function for the display device DD.

The lattice openings POP may be defined together in the dummy metal layer DMT and the support plate PLT. The grooves GV may be defined in a lower surface of the dummy metal layer DMT and may be formed to extend to a lower portion of the support plate PLT. For example, the dummy metal layer DMT may have a thickness of about 1 micrometer (μm) in the third direction DR3.

The cover layer COV may be disposed under the dummy metal layer DMT. The cover layer COV may cover the lattice openings POP. The cover layer COV may be disposed under the curved portion CSP. When viewed in the plane, the cover layer COV may overlap the curved portion CSP.

The cover layer COV may have an elastic modulus lower than that of the support plate PLT. For example, the cover layer COV may include thermoplastic polyurethane or rubber, however, the material of the cover layer COV is not limited thereto or thereby. The cover layer COV may be manufactured in a form of a sheet and attached to the support plate PLT. As an example, the cover layer COV may have a thickness of about 16 micrometers (μm) in the third direction DR3.

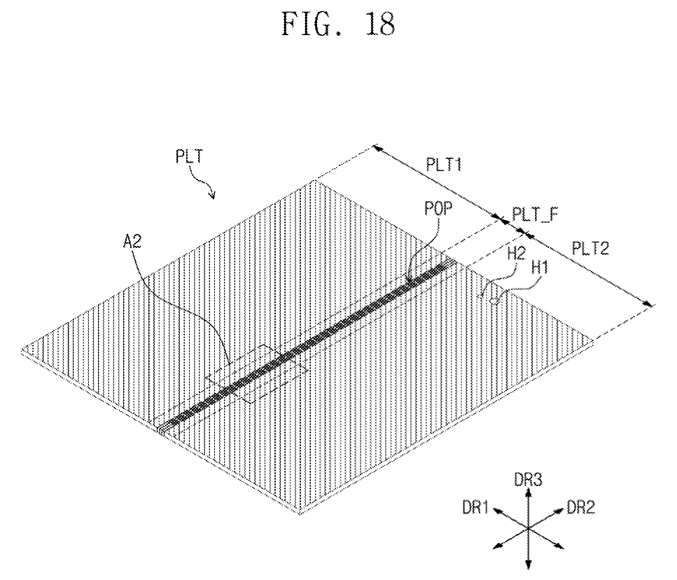

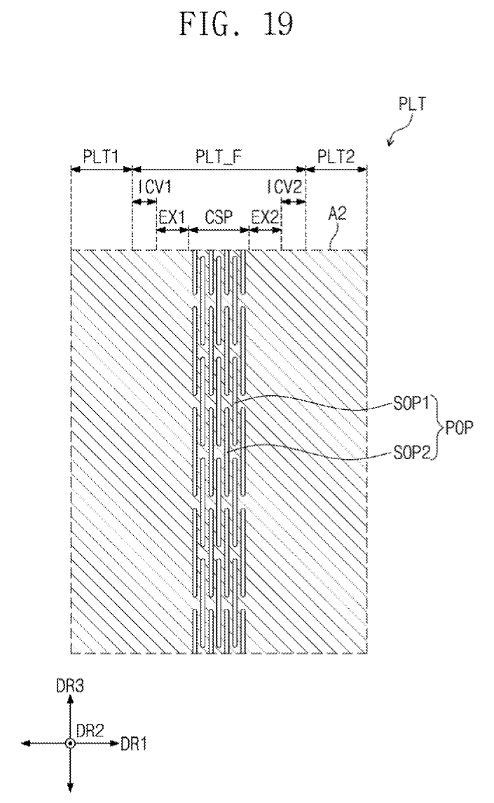

FIG. 18 is a perspective view of the support plate shown in FIG. 17. FIG. 19 is an enlarged plan view of a second area A2 shown in FIG. 18.

Referring to FIGS. 18 and 19, the support plate PLT may include the first support plate PLT1, the folding portion PLT_F, and the second support plate PLT2, which are arranged in the first direction DR1. The folding portion PLT_F may include the first reverse curvature portion ICV1, the first extension portion EX1, the curved portion CSP, the second extension portion EX2, and the second reverse curvature portion ICV2, which are arranged in the first direction DR1.

A lattice pattern may be defined in the curved portion CSP. As an example, the lattice openings POP defined in the curved portion CSP may be arranged in a certain rule. The lattice openings POP may be arranged in a lattice structure to form the lattice pattern of the curved portion CSP.

A first hole H1 and a second hole H2 may be defined in the second support plate PLT2. The first hole H1 and the second hole H2 may be arranged adjacent to an edge of the second support plate PLT2. The camera CA and the sensor SN, described above, may be disposed in the first hole H1 and the second hole H2, respectively.

The lattice openings POP may extend longer in the second direction DR2 than in the first direction DR1. The lattice openings POP may include a plurality of first sub-openings SOP1 arranged in the second direction DR2 and a plurality of second sub-openings SOP2 arranged in the second direction DR2 adjacent to the first sub-openings SOP1 in the first direction DR1. The first sub-openings SOP1 may be arranged in a staggered manner with respect to the second sub-openings SOP2.

FIG. 20 is a view illustrating a folded state of the display device shown in FIG. 17.

As an example, in FIG. 20, the display module DM is illustrated as a single layer, and the cover layer COV and dummy metal layer DMT are omitted for brevity of description. As an example, the boundaries of the first and second support plates PLT1 and PLT2, the curved portion CSP, the first and second extension portions EX1 and EX2, and the first and second reverse curvature portions ICV1 and ICV2 are illustrated by dotted lines on the support plate PLT.

Referring to FIG. 20, the support plate PLT may be folded about the folding axis FX. The support plate PLT may be folded into a dumbbell shape. Since the support plate PLT is folded, the display module DM may be folded together with the support plate PLT.

The folding portion PLT_F may be folded about the folding axis FX, and thus, the support plate PLT may be folded. When the folding portion PLT_F is folded, the curved portion CSP may be bent to have a selected curvature. Since the lattice openings POP are defined in the curved portion CSP, flexibility of the curved portion CSP may increase. Accordingly, the curved portion CSP may be bent more easily due to the lattice openings POP. The folding area FA of the display module DM on the curved portion CSP may be bent to have a radius of curvature R.

When the folding portion PLT_F is folded, the first reverse curvature portion ICV1 may be bent in a direction opposite to that of the curved portion CSP. In addition, when the folding portion PLT_F is folded, the second reverse curvature portion ICV2 may also be bent in a direction opposite to that of the curved portion CSP. The second reverse curvature portion ICV2 may have a shape that is symmetrical to the first reverse curvature portion ICV1.

Since the grooves GV are defined in the lower surfaces of the first and second reverse curvature portions ICV1 and ICV2, flexibility of the first and second reverse curvature portions ICV1 and ICV2 may increase. Accordingly, the first and second reverse curvature portions ICV1 and ICV2 may be bent more easily due to the grooves GV.

When the folding portion PLT_F is folded, the first support plate PLT1 and the second support plate PLT2 may be maintained in a flat state. Accordingly, the first and second non-folding areas NFA1 and NFA2 may be maintained in a flat state by the first and second support plates PLT1 and PLT2.

When the folding portion PLT_F is folded, a gap GP between the first support plate PLT1 and the second support plate PLT2 in the first direction DR1 may be smaller than a diameter of a circle with the radius of curvature R. According to this configuration, the support plate PLT may be folded into the dumbbell shape.

The first extension portion EX1 may be maintained in a flat state between the curved portion CSP and the first reverse curvature portion ICV1. The first extension portion EX1 may extend flat from the first reverse curvature portion ICV1 toward the curved portion CSP.

The second extension portion EX2 may be maintained in a flat state between the curved portion CSP and the second reverse curvature portion ICV2. The second extension portion EX2 may extend flat from the second reverse curvature portion ICV2 toward the curved portion CSP.

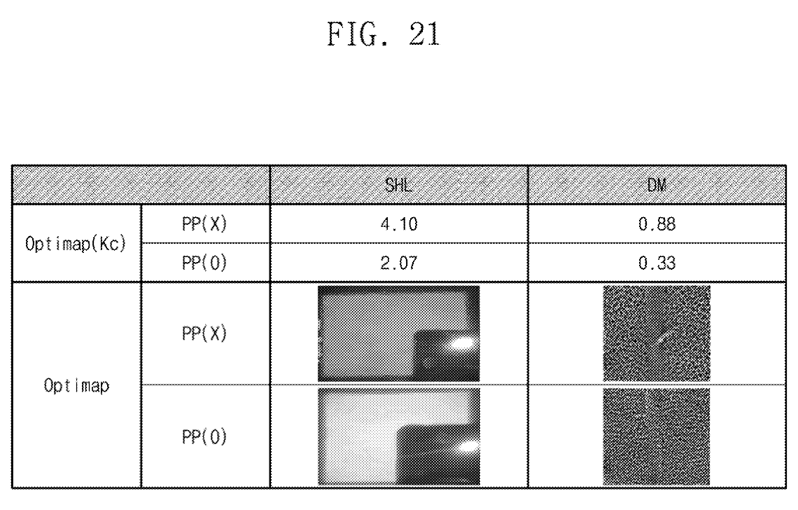

FIG. 21 is a diagram illustrating results of measuring flatness of the shielding layer without the planarization layer, the shielding layer with the planarization layer, the display module including the shielding layer without the planarization layer, and the display module including the shielding layer with the planarization layer, which are measured using Optimap, as an example of a surface measurement device.

In FIG. 21, a symbol X indicates a state in which the upper and lower surfaces of the shielding layer SHL are not coated with the planarization layer PP, and a symbol O indicates a state in which the upper and lower surfaces of the shielding layer SHL are coated with the planarization layer PP. Optimap (Kc) represents measured values from the Optimap equipment, and as a numerical value decrease, it means that the measured surface of a corresponding component may be flatter. Flatness of the upper surface of the shielding layer SHL and flatness of the upper surface of the display module DM were measured using the Optimap. For the shielding layer SHL coated with the planarization layer PP, the flatness of the upper surface of the first planarization layer PP1, which is coated on the upper surface of the shielding layer SHL, was measured.

The measured flatness value was smaller for the shielding layer SHL coated with the planarization layer PP than for the shielding layer SHL not coated with the planarization layer PP. In addition, an image appeared brighter (indicating higher flatness) in the shielding layer SHL coated with the planarization layer PP than in the shielding layer not coated with the planarization layer PP. Accordingly, the shielding layer SHL coated with the planarization layer PP may have improved flatness compared to the shielding layer SHL not coated with the planarization layer PP.

The measured value for flatness was smaller in the display module DM including the shielding layer SHL coated with the planarization layer PP than in the display module DM including the shielding layer not coated with the planarization layer PP. In addition, in the display module DM including the shielding layer SHL coated with the planarization layer PP, dots in an image appeared smaller and denser than those in the display module DM including the shielding layer not coated with the planarization layer PP. The image may indicate that the display module DM including the shielding layer SHL coated with the planarization layer PP has improved flatness.

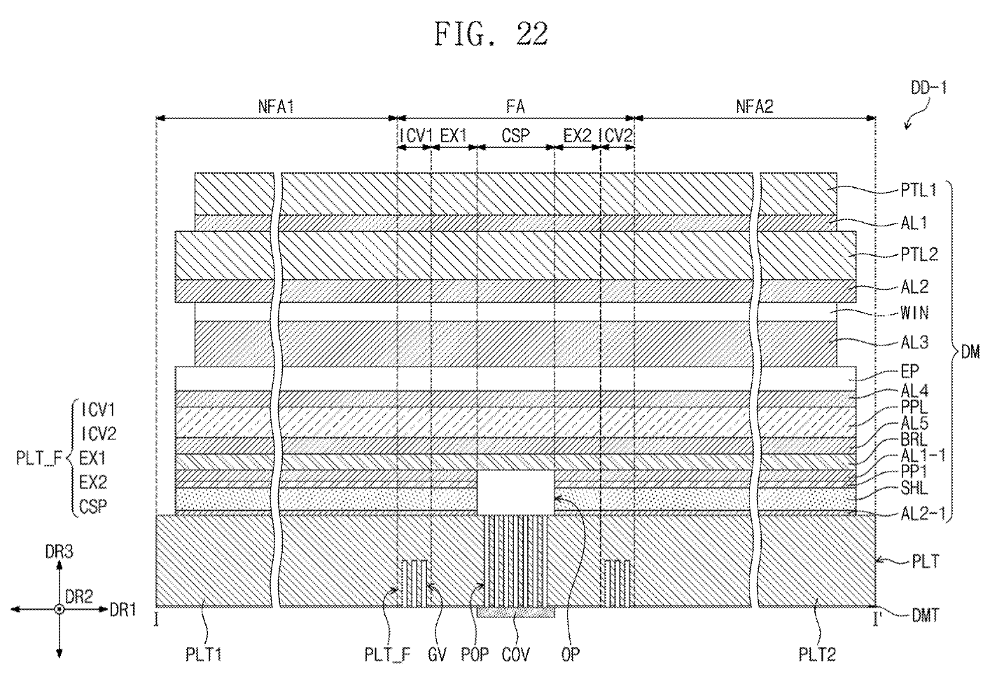

FIG. 22 is a cross-sectional view of a display device according to an embodiment of the present disclosure.

As an example, FIG. 22 illustrates a cross-section corresponding to that of FIG. 17, and hereinafter, components shown in FIG. 22 will be described focusing on the differences from those shown in FIG. 17.

Referring to FIG. 22, a display device DD-1 may include a first planarization layer PP1 coated on an upper surface of a shielding layer SHL. Different from the display device DD shown in FIG. 17, the display device DD-1 shown in FIG. 22 may not include the second planarization layer PP2 coated on a lower surface of the shielding layer SHL. A second adhesive layer AL2-1 may be disposed between the shielding layer SHL and a support plate PLT, and the shielding layer SHL and the support plate PLT may be bonded to each other by the second adhesive layer AL2-1.

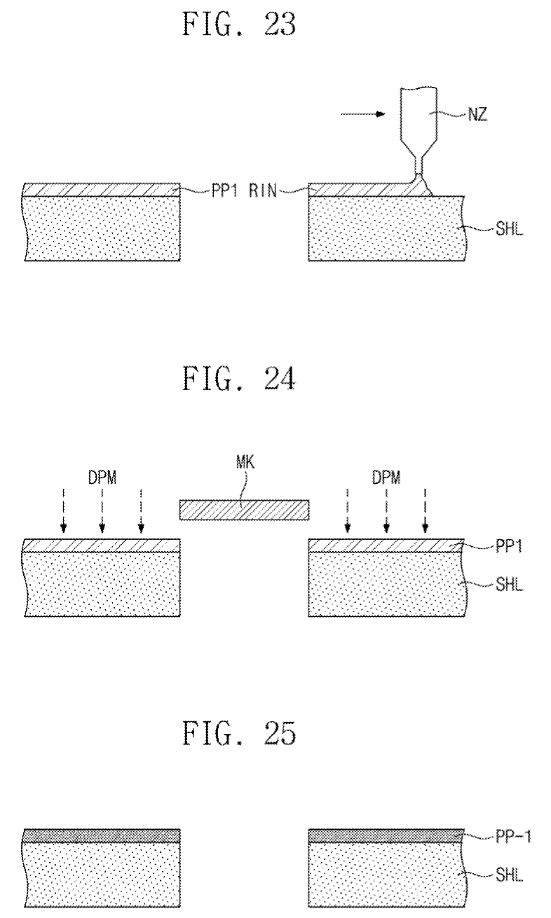

FIGS. 23 and 24 are diagrams illustrating a manufacturing method of providing the first planarization layer on the upper surface of the shielding layer according to one or more embodiments of the present disclosure.

Referring to FIG. 23, a resin RIN may be coated on the upper surface of the shielding layer SHL through a nozzle NZ. The resin RIN may be cured to form the first planarization layer PP1. Although not shown in figures, the second planarization layer PP2 may also be formed in the same or similar manner.

Referring to FIG. 24, a deposition material DPM may be deposited on the upper surface of the shielding layer SHL exposed through a mask MK, and thus, the first planarization layer PP1 may be formed. Although not shown in figures, the second planarization layer PP2 may also be formed in the same or similar manner.

FIG. 25 is a diagram illustrating a first planarization layer according to an embodiment of the present disclosure.

Referring to FIG. 25, the first planarization layer PP1-1 may have a black color. In this case, when viewing the display module DM from above the display module DM, components disposed under the first planarization layer PP1-1 may not be visible.

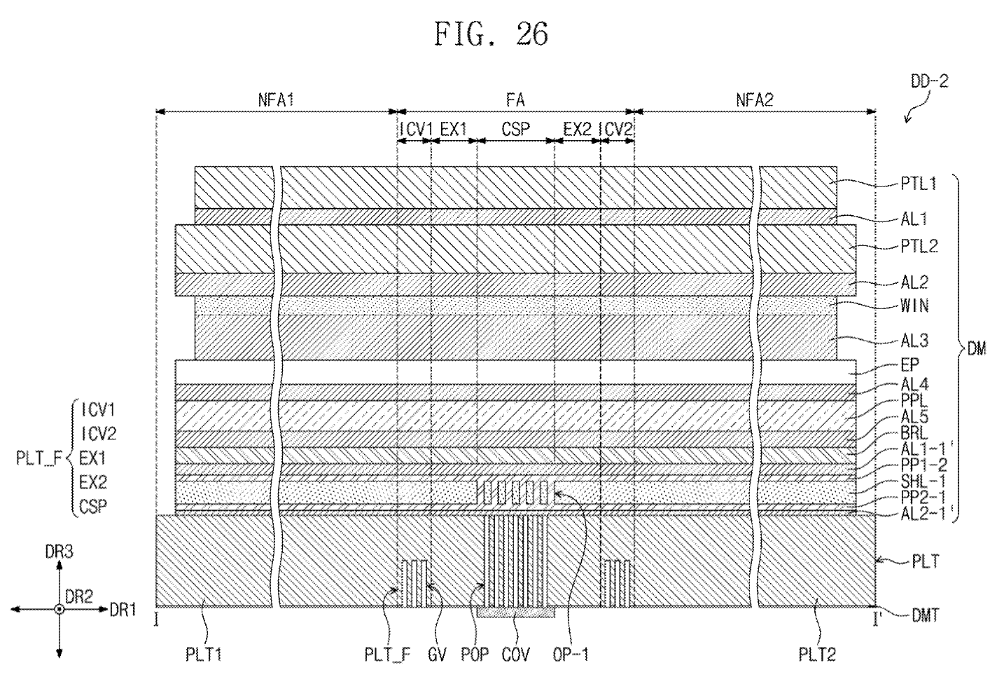

FIGS. 26-28 are cross-sectional views of display devices according to various embodiments of the present disclosure.

For example, FIGS. 26-28 illustrate cross-sections corresponding to that of FIG. 17, and hereinafter, components shown in FIGS. 26-28 will be described focusing on the differences from those shown in FIG. 17.

Referring to FIG. 26, the above-described opening OP in FIG. 17 may not be defined in a first adhesive layer AL1-1’ and a second adhesive layer AL2-1’ of a display device DD-2. Accordingly, the first adhesive layer AL1-1’ and the second adhesive layer AL2-1’ may overlap the first and second non-folding areas NFA1 and NFA2 and the folding area FA.

An electromagnetic shielding layer SHL-1 of the display device DD-2 may overlap the first and second non-folding areas NFA1 and NFA2 and the folding area FA. A plurality of openings OP-1 may be defined in the electromagnetic shielding layer SHL-1 to overlap the folding area FA.

A first planarization layer PP1-2 and a second planarization layer PP2-1 may be formed integrally with each other and may be disposed in the openings OP-1. In addition, the first planarization layer PP1-2 and the second planarization layer PP2-1 may be disposed between the first adhesive layer AL1-1’ and the second adhesive layer AL2-1’.

Since the openings OP-1 are defined in the electromagnetic shielding layer SHL-1 overlapping the folding area FA, the flexibility of the folding area FA may be improved. In addition, as the openings OP-1 are filled with the first planarization layer PP1-2 and the second planarization layer PP2-1, impact resistance of the folding area FA may be enhanced.

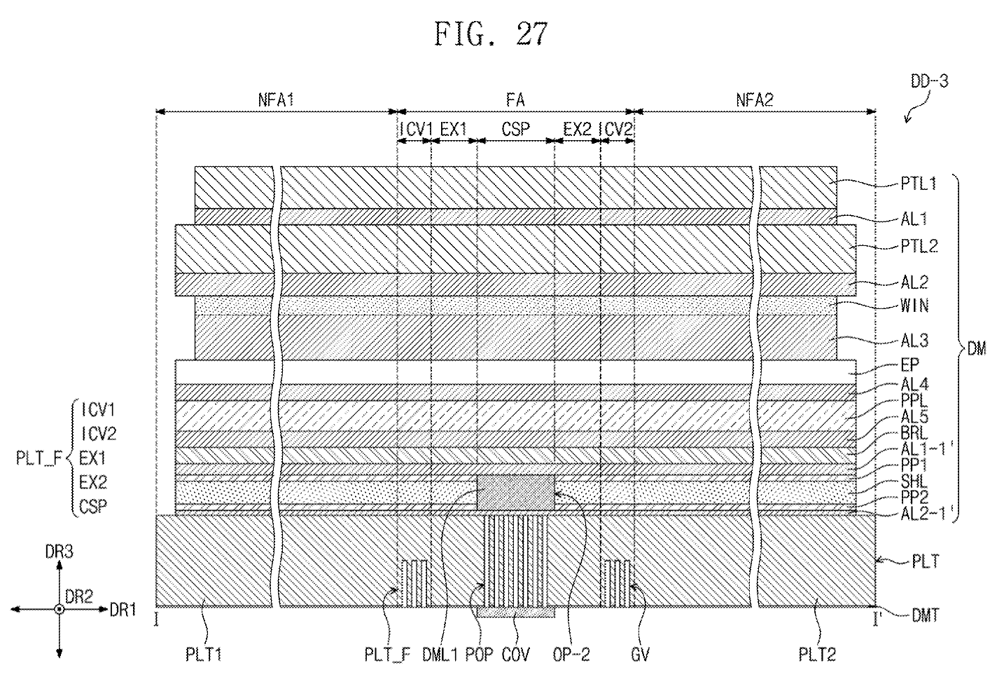

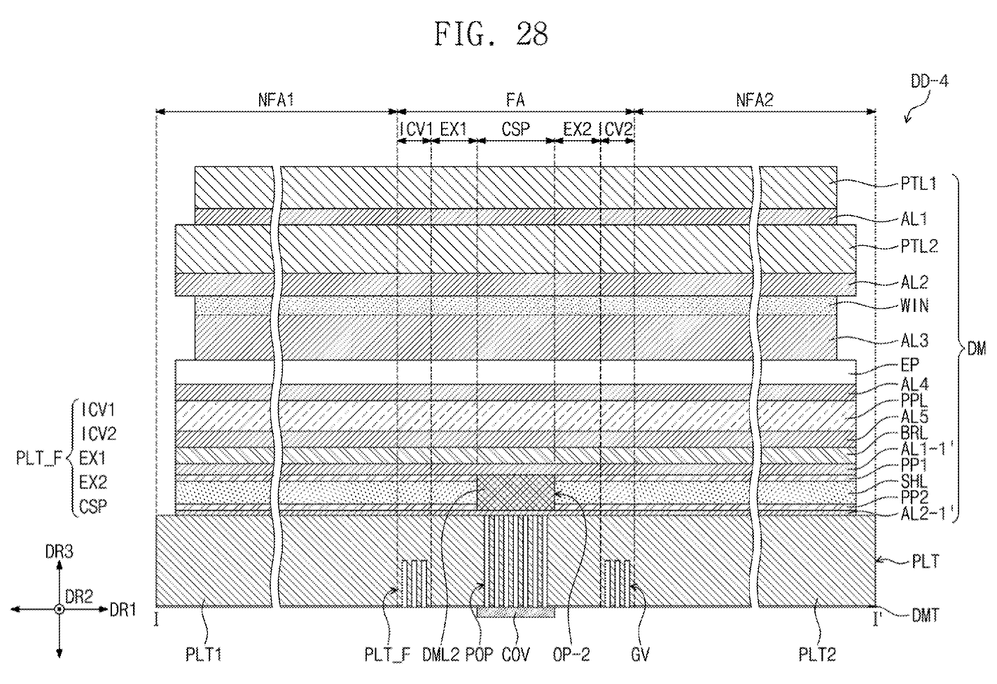

Referring to FIGS. 27 and 28, since the above-described opening OP in FIG. 17 is not defined in first and second adhesive layers AL1-1’ and AL2-1’ of a display device DD-3 and a display device DD-4, the first and second adhesive layers AL1-1’ and AL2-1’ may overlap the first and second non-folding areas NFA1 and NFA2 and the folding area FA.

In each of the display devices DD-3 and DD-4, an opening OP-2 may be defined in an electromagnetic shielding layer SHL and first and second planarization layers PP1 and PP2. Dummy layers DML1 and DML2 may be respectively disposed in the openings OP-2 of the display devices DD-3 and DD-4. In each of the display devices DD-3 and DD-4, the first adhesive layer AL1-1’ and the second adhesive layer AL2-1’ may seal the opening OP-2. Accordingly, in the opening OP-2 of each of the display devices DD-3 and DD-4, each of the dummy layers DML1 and DML2 may be disposed between the first adhesive layer AL1-1’ and the second adhesive layer AL2-1’.

The dummy layers DML1 and DML2 may include different materials. The dummy layer DML1 may include thermoplastic polyurethane. The dummy layer DML2 may include various resins. Since the dummy layers DML1 and DML2 are disposed in the openings OP-2 of the display devices DD-3 and DD-4, the impact resistance of the folding area FA may be improved.

According to example embodiments of the present disclosure, since the input sensing part senses the first input generated by the user’s touch and the second input generated by the pen, a separate digitizer is not required, and thus the thickness of the display device is reduced.

In addition, as the first and second planarization layers with high flatness are disposed on upper and lower surfaces of the electromagnetic shielding layer, which is disposed under the display panel, the surface quality of the display device is enhanced.

Although several example embodiments of the present disclosure have been described, it is understood that the present disclosure is not limited to these embodiments but various changes and modifications can be made by one ordinary skilled in the art within the spirit and scope of the present disclosure as hereinafter claimed.

Therefore, the disclosed subject matter is not limited to any single embodiment described herein, and the scope of the present inventive concept shall be determined according to the attached claims and their equivalents.

What is claimed is:

1. A display device comprising:
a display panel comprising a folding area;
an input sensing part on the display panel, configured to sense a first input generated by a user’s touch and a second input generated by a pen;
a barrier layer under the display panel;
an electromagnetic shielding layer disposed under the barrier layer;
a first adhesive layer between the barrier layer and the electromagnetic shielding layer; and
a first planarization layer between the first adhesive layer and the electromagnetic shielding layer.

2. The display device of claim 1, wherein the first planarization layer has a modulus smaller than a modulus of the electromagnetic shielding layer.

3. The display device of claim 2, wherein the electromagnetic shielding layer has a modulus of about 2.8Gpa, and the first planarization layer has a modulus of about 0.6Gpa to about 1.8Gpa.

4. The display device of claim 1, wherein the first planarization layer has a thickness smaller than a thickness of the electromagnetic shielding layer.

5. The display device of claim 4, wherein the first planarization layer has a thickness of about 1 micrometer to about 10 micrometers.

6. The display device of claim 4, wherein the electromagnetic shielding layer has a thickness of about 20 micrometers to about 50 micrometers.

7. The display device of claim 1, wherein the first planarization layer is coated on an upper surface of the electromagnetic shielding layer.

8. The display device of claim 7, wherein the first planarization layer is in direct contact with the upper surface of the electromagnetic shielding layer.

9. The display device of claim 1, wherein the first planarization layer comprises a resin.

10. The display device of claim 9, wherein the first planarization layer comprises a urethane acrylate-based resin.

11. The display device of claim 1, wherein the first planarization layer is deposited on an upper surface of the electromagnetic shielding layer.

12. The display device of claim 1, wherein the first planarization layer has a black color.

13. The display device of claim 1, further comprising:
a support plate under the electromagnetic shielding layer, comprising a plurality of lattice openings overlapping the folding area;
a second adhesive layer between the support plate and the electromagnetic shielding layer; and
a second planarization layer between the electromagnetic shielding layer and the second adhesive layer.

14. The display device of claim 13, wherein the second planarization layer comprises at least one of a same material, a same modulus, and a same thickness as the first planarization layer.

15. The display device of claim 13, wherein the second planarization layer is coated on and is in direct contact with a lower surface of the electromagnetic shielding layer.

16. The display device of claim 13, wherein the electromagnetic shielding layer, the first and second planarization layers, and the first and second adhesive layers comprise an opening overlapping the folding area.

17. The display device of claim 13, wherein the electromagnetic shielding layer comprises a plurality of openings overlapping the folding area, and
wherein the first planarization layer is formed integrally with the second planarization layer and the first and second planarization layers are in the plurality of openings.

18. The display device of claim 16, further comprising a dummy layer in the opening,
wherein the dummy layer is between the first adhesive layer and the second adhesive layer.

19. A display device comprising:
a display panel comprising a folding area;
an input sensing part on the display panel, configured to sense a first input generated by a user’s touch and a second input generated by a pen;
an electromagnetic shielding layer under the display panel;
a support plate under the electromagnetic shielding layer, comprising a plurality of lattice openings defined therethrough and overlapping the folding area;
a first planarization layer between the display panel and the electromagnetic shielding layer; and
a second planarization layer between the support plate and the electromagnetic shielding layer, wherein the first and second planarization layers each have a modulus smaller than a modulus of the electromagnetic shielding layer, and each have a thickness smaller than a thickness of the electromagnetic shielding layer.

20. An electronic device comprising:
at least one processor; and
a display device configured to receive an image signal from the at least one processor and provide an image corresponding to the image signal, the display device comprising:
a display panel comprising a folding area;
an input sensing part on the display panel, configured to sense a first input generated by a user’s touch and a second input generated by a pen;
a barrier layer under the display panel;
an electromagnetic shielding layer under the barrier layer;
a first adhesive layer between the barrier layer and the electromagnetic shielding layer; and
a first planarization layer between the first adhesive layer and the electromagnetic shielding layer.
